(19) United States
(12) Patent Application Publication
(10) Pub. No.: US 2024/0421260 A1
(43) Pub. Date: Dec. 19, 2024

(54) LIGHT EMITTING ELEMENT AND DISPLAY DEVICE INCLUDING THE SAME

(71) Applicant: Samsung Display Co., LTD., Yongin-si (KR)

(72) Inventors: Seul Ki KIM, Yongin-si (KR); Hye Lim KANG, Yongin-si (KR); Myeong Hee KIM, Yongin-si (KR); Dal Rae JIN, Yongin-si (KR); Kook Hyun HAN, Yongin-si (KR)

(21) Appl. No.: 18/587,670

(22) Filed: Feb. 26, 2024

(30) Foreign Application Priority Data
Jun. 19, 2023 (KR) 10-2023-0077990

(51) Int. Cl. H01L 33/46; H01L 25/16; H01L 33/20

(52) U.S. Cl. CPC H01L 33/46; H01L 25/167; H01L 33/20

(57) ABSTRACT

A light-emitting element includes a second semiconductor layer, an active layer above the second semiconductor layer, a first semiconductor layer above the active layer, a first insulating layer surrounding side surfaces of the first semiconductor layer, the active layer, and the second semiconductor layer and an upper surface of the first semiconductor layer, and defining a first opening at the upper surface of the first semiconductor layer, a reflective layer surrounding side surfaces of the first semiconductor layer and the active layer and an upper surface of the first semiconductor layer on the first insulating layer, and a second insulating layer on the reflective layer and on a portion of the first insulating layer on which the reflective layer is not located, defining a second opening on an upper surface of the first semiconductor layer, and having one end having a step with one end of the reflective layer.

### CROSS-REFERENCE TO RELATED APPLICATION

The present application claims priority to, and the benefit of, Korean Patent Application No. 10-2023-0077990, filed on Jun. 19, 2023, in the Korean Intellectual Property Office, the entire disclosure of which is incorporated herein by reference.

### BACKGROUND

### 1. Field

The present disclosure relates to a light-emitting element and a display device including the same.

### 2. Description of the Related Art

Display devices are becoming increasingly important with the development of multimedia. In response to this, various types of display devices, such as organic light-emitting displays (OLED) and liquid crystal displays (LCD), are being used.

### SUMMARY

A device for displaying an image of a display device includes a display panel, such as an organic light-emitting display panel or a liquid crystal display panel. Among them, the light-emitting display panel may include a light-emitting element. For example, light-emitting diodes (LED) include organic light-emitting diodes (OLED) that utilize organic materials as light-emitting materials, inorganic light-emitting diodes that utilize inorganic materials as light-emitting materials, and/or the like.

Aspects of embodiments of the present disclosure provide a light-emitting element capable of reducing or preventing the likelihood of a short circuit between a first electrode and a second electrode of the light-emitting element and a display device including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a light-emitting element includes a second semiconductor layer, an active layer above the second semiconductor layer, a first semiconductor layer above the active layer, a first insulating layer surrounding side surfaces of the first semiconductor layer, the active layer, and the second semiconductor layer and an upper surface of the first semiconductor layer, and defining a first opening at the upper surface of the first semiconductor layer, a reflective layer surrounding side surfaces of the first semiconductor layer and the active layer and an upper surface of the first semiconductor layer on the first insulating layer, and a second insulating layer on the reflective layer and on a portion of the first insulating layer on which the reflective layer is not located, defining a second opening on an upper surface of the first semiconductor layer, and having one end having a step with one end of the reflective layer.

The reflective layer may directly contact the first semiconductor layer through the first opening.

One end of the reflective layer may surround a portion of an outer surface of the second semiconductor layer on the first insulating layer, wherein the reflective layer exposes the first insulating layer corresponding to at least a portion of the second semiconductor layer.

The second insulating layer may surround side surfaces of the first semiconductor layer, the active layer, and the second semiconductor layer, and covers one end of the reflective layer.

The first semiconductor layer, the active layer, and the second semiconductor layer may be shaped like a column or like a shape that narrows in width toward the first semiconductor layer.

The light-emitting element may further include a connection electrode on the reflective layer exposed by the second opening.

The light-emitting element may further include a third semiconductor layer on one surface of the second semiconductor layer, wherein one end of the reflective layer is aligned with one end of the second semiconductor layer.

The second semiconductor layer may include a first portion having a first width, and a second portion having a second width, wherein the second width is less than the first width, wherein the second portion is closer to the connection electrode than the first portion, and wherein the first insulating layer and the reflective layer surround side surfaces of the second portion.

A width of the active layer and a width of the first semiconductor layer may be less than a width of the second portion of the second semiconductor layer.

A side surface of the reflective layer may be aligned with a side surface of the first portion of the second semiconductor layer.

The light-emitting element may further include a metal layer surrounding the second semiconductor layer on the second insulating layer, wherein the metal layer and the reflective layer do not contact each other.

The light-emitting element may further include a metal layer surrounding the first portion of the second semiconductor layer on the second insulating layer, wherein the metal layer and the reflective layer do not contact each other.

A side surface of the first insulating layer may be aligned with a side surface of a first portion of the second semiconductor layer.

The second insulating layer may cover one end of the reflective layer.

The light-emitting element may further include a connection electrode on the reflective layer exposed by the second opening.

According to an aspect of the present disclosure, a display device includes a substrate, a pixel electrode above the substrate, light-emitting elements above the pixel electrode, an organic layer above the pixel electrode, and between the light-emitting elements, and a common electrode above the organic layer and the light-emitting elements, wherein the light-emitting elements include, a second semiconductor layer, an active layer above the second semiconductor layer, a first semiconductor layer above the active layer, a first insulating layer surrounding side surfaces of the first semiconductor layer, the active layer, and the second semiconductor layer and an upper surface of the first semiconductor layer, and defining a first opening at the upper surface of the first semiconductor layer, a reflective layer surrounding side surfaces of the first semiconductor layer and the active layer and an upper surface of the first semiconductor layer on the first insulating layer, and a second insulating layer on the reflective layer and a portion of the first insulating layer on which the reflective layer is not located, defining a second opening on an upper surface of the first semiconductor layer, and having one end having a step with one end of the reflective layer.

The light-emitting elements may further include a connection electrode on the reflective layer exposed by the second opening, wherein the connection electrode is connected to the pixel electrode, and wherein the second semiconductor layer is connected to the common electrode.

One end of the reflective layer may surround a portion of an outer surface of the second semiconductor layer on the first insulating layer, wherein the reflective layer exposes a first insulating layer corresponding to at least a portion of the second semiconductor layer.

The second insulating layer may surround side surfaces of the first semiconductor layer, the active layer, and the second semiconductor layer, and covers one end of the reflective layer.

The reflective layer might not contact the common electrode.

A light-emitting element and a display device including the same according to one or more embodiments may reduce or prevent the likelihood of an electrical short circuit that may otherwise occur when conducting a connection electrode and a common electrode through a reflective layer.

It should be noted that the aspects of the present disclosure are not limited to those described above, and other aspects of the present disclosure will be apparent from the following description.

However, the aspects of the present disclosure are not limited to the aforementioned aspects, and various other aspects are included in the present specification.

### BRIEF DESCRIPTION OF THE DRAWINGS

FIG. 1 is a plan view of a display device according to one or more embodiments.

FIG. 2 is a schematic layout view of a circuit of a display substrate of a display device according to one or more embodiments.

FIG. 3 is an equivalent circuit diagram of one-pixel of a display device according to one or more embodiments.

FIG. 4 is an equivalent circuit diagram of one-pixel of a display device according to one or more other embodiments.

FIG. 5 is an equivalent circuit diagram of one-pixel of a display device according to one or more other embodiments.

FIG. 6a is a schematic cross-sectional view of a display device according to one or more embodiments.

FIG. 6b is a schematic cross-sectional view of a display device according to one or more other embodiments.

FIG. 7 is a plan view illustrating light-emitting areas of a display device according to one or more embodiments.

FIG. 8 is an enlarged view of area A of FIG. 6a.

FIGS. 9a and 9b are cross-sectional views schematically illustrating a structure of a light-emitting element according to one or more embodiments.

FIG. 10 is a cross-sectional view schematically illustrating a structure of a light-emitting element according to one or more other embodiments.

FIG. 11 is a cross-sectional view schematically illustrating a structure of a light-emitting element according to one or more other embodiments.

FIG. 12 is a plan view illustrating a second semiconductor layer of a light-emitting element.

FIG. 13 is a diagram illustrating a light-emitting element according to one or more other embodiments.

FIG. 14 is a diagram illustrating a light-emitting element according to one or more other embodiments.

FIG. 15 is a diagram illustrating a light-emitting element according to one or more other embodiments.

FIG. 16 is a flowchart illustrating a method of manufacturing a display device according to one or more embodiments.

FIGS. 17 to 37 are diagrams to illustrate a method of manufacturing a display device according to one or more embodiments.

FIG. 38 is a diagram schematically showing a virtual reality device including a display device according to one or more embodiments;

FIG. 39 is a diagram schematically showing a smart device including a display device according to one or more embodiments;

FIG. 40 is a diagram schematically showing a vehicle including a display device according to one or more embodiments.

FIG. 41 is a diagram schematically showing a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

When one or more embodiments may be implemented differently, a specific process order may be performed differently from the described order. For example, two consecutively described processes may be performed substantially at the same time or performed in an order opposite to the described order.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

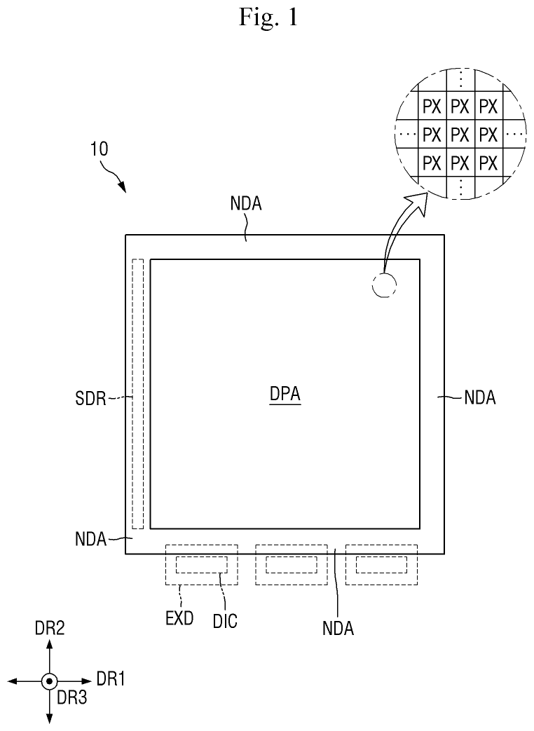

FIG. 1 is a plan view of a display device according to one or more embodiments.

Referring to FIG. 1, a display device 10 according to one or more embodiments may be applied to various consumer electronics, or internet of things devices, such as smartphones, cell phones, tablet PC, personal digital assistants (PDA), portable multimedia players (PMP), televisions, gaming devices, watch-type electronic devices, head-mounted displays, monitors of personal computers, laptop computers, car navigation, car instrument panels, digital cameras, camcorders, exterior billboards, billboards, medical devices, inspection devices, refrigerators, and washing machines, and/or the like. A television is described herein as an example of the display device, and the television may have a high or ultra-high resolution, such as HD, UHD, 4K, 8K, etc.

In addition, the display device 10 according to some embodiments may be variously categorized based on how it is displayed. For example, the classification of the display device may include an organic light-emitting display device (OLED), an inorganic light-emitting display device (inorganic EL), a quantum dot light-emitting display device (QED), a micro-LED display device (micro-LED), a nano-LED display device (nano-LED), a plasma display device (PDP), a field emission display device (FED), a cathode ray tube display device (CRT), a liquid crystal display device (LCD), an electrophoretic display device (EPD), and/or the like. In the following, the organic light-emitting display device will be described as an example of a display device, and the organic light-emitting display device applied in one or more embodiments will be abbreviated simply as a display device unless otherwise indicated. However, embodiments are not limited to organic light-emitting display device, and other display devices listed above or known in the art may be employed to the extent that they share technical ideas.

Furthermore, in the following drawings, a first direction DR1 refers to a horizontal direction of the display device 10, a second direction DR2 refers to a vertical direction of the display device 10, and a third direction DR3 refers to a thickness direction of the display device 10. In this case, “left,” “right,” “up,” and “down” refer to directions when the display device 10 is viewed from a plane. For example, “right” refers to one side of the first direction DR1, “left” refers to the other side of the first direction DR1, “top” refers to one side of the second direction DR2, and “bottom” refers to the other side of the second direction DR2. Further, “upper” refers to a first side of the third direction DR3 and “lower” refers to a second side of the third direction DR3.

The display device 10 according to one or more embodiments may have a square shape in plan view, for example, a square shape. Also, if the display device 10 is a television, it may have a rectangular shape with the long sides located in the transverse direction. However, it is not limited to this, the long sides may be located in the longitudinal direction, and it may be rotatably mounted so that the long sides are variably located in the horizontal or vertical direction. The display device 10 may also have a circular or oval shape.

The display device 10 may include a display area DPA and a non-display area NDA. The display area DPA may be an active area where the video is displayed. The display area DPA may have a square shape in plan view that is similar to the overall shape of the display device 10, but is not limited thereto.

The display area DPA may include a plurality of pixels PX. The plurality of pixels PX may be arranged in a matrix orientation. The shape of each pixel PX may be rectangular or square in plan view, but is not limited thereto, and may also be rhombic in shape with each side inclined toward one side of the display device 10. The plurality of pixels PX may include multiple color pixels PX. For example, the plurality of pixels may include a first color pixel PX of red, a second color pixel PX of green, and a third color pixel PX of blue but are not limited thereto. Each color pixel PX may be alternately arranged in a stripe-type or a PenTile™-type (PenTile™ and PENTILE™ being a registered trademark of Samsung Display Co., Ltd., Republic of Korea).

The non-display area NDA may be located on the periphery of the display area DPA. The non-display area NDA may fully or partially enclose the display area DPA. The display area DPA may be square in shape, and the non-display areas NDA may be arranged to be adjacent to the four sides of the display area DPA. The non-display area NDA may comprise a bezel of the display device 10.

A driving circuit or a driving element for driving the display area DPA may be located in the non-display area NDA. In one or more embodiments, the non-display area NDA located adjacent to the first side (lower side in FIG. 1) of the display device 10 may have a pad portion provided on the display substrate of the display device 10, and an external device EXD may be mounted on the pad electrode of the pad portion. Examples of the external device EXD include a connection film, a printed circuit board, a driving chip (DIC), a connector, a wiring connection film, and/or the like. In the non-display area NDA located adjacent to the second side (left side in FIG. 1) of the display device 10, a scan driver SDR, or the like formed directly on the display substrate of the display device 10 may be located.

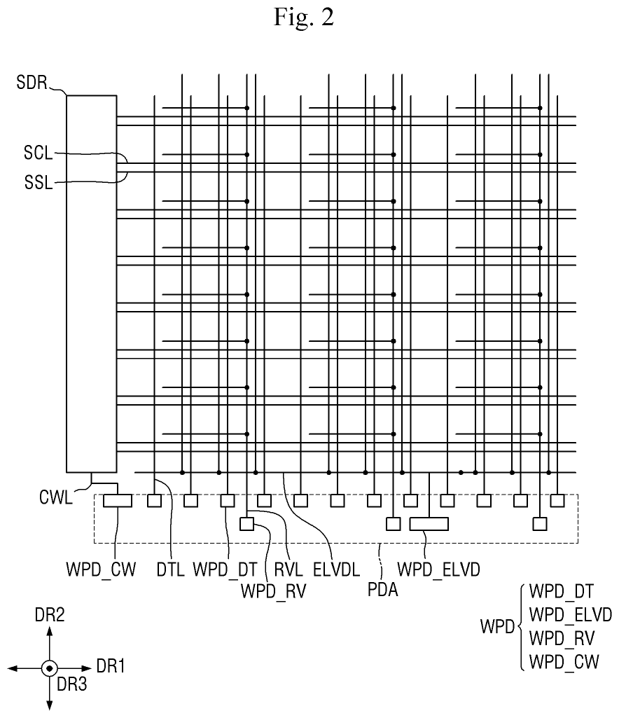

FIG. 2 is a schematic layout view of a circuit of a display substrate of a display device according to one or more embodiments.

Referring to FIG. 2, a plurality of lines is located on the substrate. The plurality of lines may include a scan line SCL, a sensing signal line SSL, a data line DTL, a reference voltage line RVL, a first power supply line ELVDL, and/or the like.

The scan line SCL and the sensing signal line SSL may be extended in the first direction DR1. The scan line SCL and the sensing signal line SSL may be connected to the scan driver SDR. The scan driver SDR may include a driving circuit. The scan driver SDR may be located on one side of the non-display area NDA on the display substrate but may also be located on both sides of the non-display area NDA. The scan driver SDR may be connected to a signal connection line CWL, and at least one end of the signal connection line CWL may be connected to an external device (“EXD” in FIG. 1) by forming a pad (WPD_CW) on the first non-display area NDA and/or the second non-display area NDA.

The data line DTL and the reference voltage line RVL may be extended in the second direction DR2 crossing the first direction DR1. The first power supply line ELVDL may include a portion extending in the second direction DR2. The first power supply line ELVDL may further include a portion extending in the first direction DR1. The first power supply line ELVDL may have a mesh structure, but is not limited thereto.

Wiring pads WPD may be located at at least one end of the data line DTL, the reference voltage line RVL, and the first power supply line ELVDL. Each wiring pad WPD may be located on a pad area PDA of the non-display area (NDA). In one or more embodiments, a wiring pad (WPD_DT, hereinafter referred to as a “data pad”) for a data line DTL, a wiring pad (WPD_RV, hereinafter referred to as a “reference voltage pad”) for the reference voltage line RVL, and a wiring pad (WPD_ELVD, hereinafter referred to as a “first power pad”) for a first power supply line ELVDL may be located on the pad area PDA of the non-display area NDA. In another example, the data pad WPD_DT, the reference voltage pad WPD_RV, and the first power supply pad WPD_ELVD may be located in different non-display areas NDA. An external device (“EXD” in FIG. 1) may be mounted on the wiring pad WPD as described above. The external device EXD may be mounted on the wiring pad WPD through an anisotropic conductive film, ultrasonic bonding, or the like.

Each pixel PX on the display board includes a pixel driving circuit. The wiring described above may pass through or around each pixel PX and apply a driving signal to each pixel driving circuit. The pixel driving circuit may include a transistor and a capacitor. The number of transistors and capacitors in each pixel driving circuit may be varied. Hereinafter, the pixel driving circuit will be described as a 3T1C structure including three transistors and one capacitor, but is not limited thereto, and various other modified pixel PX structures, such as a 2T1C structure, a 7T1C structure, and a 6T1C structure may be applied.

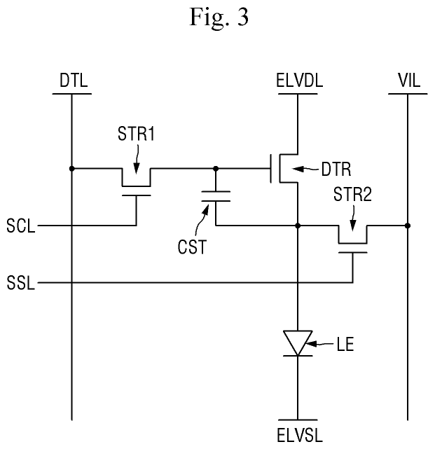

FIG. 3 is an equivalent circuit diagram of one-pixel of a display device according to one or more embodiments.

Referring to FIG. 3, each pixel PX of the display device according to one or more embodiments includes, in addition to the light-emitting element LE, three transistors DTR, STR1, and STR2 and one capacitor CST for storage.

The light-emitting element LE emits light in response to a current supplied through a driving transistor DTR. The light-emitting element LE may be implemented as an inorganic light-emitting diode, an organic light-emitting diode, a micro light-emitting diode, a nano light-emitting diode, or the like.

A first electrode (e.g., an anode electrode) of the light-emitting element LE may be connected to a source electrode of the driving transistor DTR, and a second electrode (e.g., a cathode electrode) may be connected to a second power supply line ELVSL supplied with a low potential voltage (second power supply voltage) that is lower than a high potential voltage (first power supply voltage) of the first power supply line ELVDL.

The driving transistor DTR adjusts the current flowing to the light-emitting element LE from the first power supply line ELVDL supplied with the first power voltage according to the voltage difference between a gate electrode and the source electrode. The gate electrode of the driving transistor DTR may be connected to the first electrode of the first transistor ST1, the source electrode may be connected to the first electrode of the light-emitting element LE, and a drain electrode may be connected to the first power supply line ELVDL to which the first power supply voltage is applied.

A first transistor STR1 is turned-on by a scan signal on the scan line SCL to connect the data line DTL to the gate electrode of the driving transistor DTR. The gate electrode of the first transistor STR1 may be connected to the scan line SL, the first electrode may be connected to the gate electrode of the driving transistor DTR, and the second electrode may be connected to the data line DTL.

A second transistor STR2 is turned-on by a sensing signal on the sensing signal line SSL to connect an initialization voltage line VIL to the source electrode of the driving transistor DTR. The gate electrode of the second transistor ST2 may be connected to the sensing signal line SSL, the first electrode may be connected to the initialization voltage line VIL, and the second electrode may be connected to the source electrode of the driving transistor DTR.

In one or more embodiments, the first electrode of each of the first and second transistors STR1 and STR2 may be the source electrode and the second electrode may be the drain electrode, but is not limited to, and may be vice versa.

The capacitor CST is formed between the gate and source electrodes of the driving transistor DTR. A storage capacitor CST stores the difference voltage between the gate voltage of the driving transistor DTR and the source voltage.

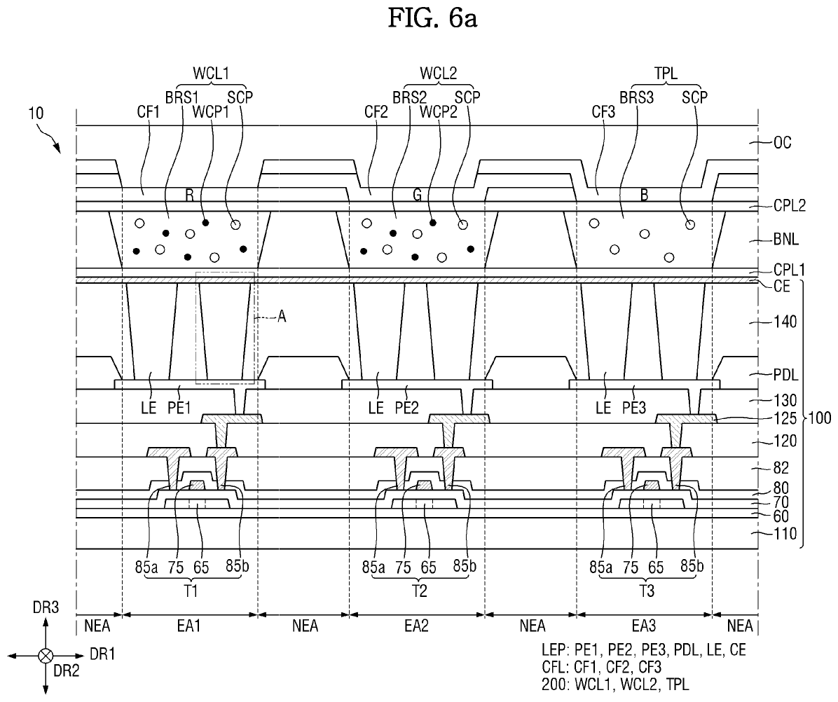

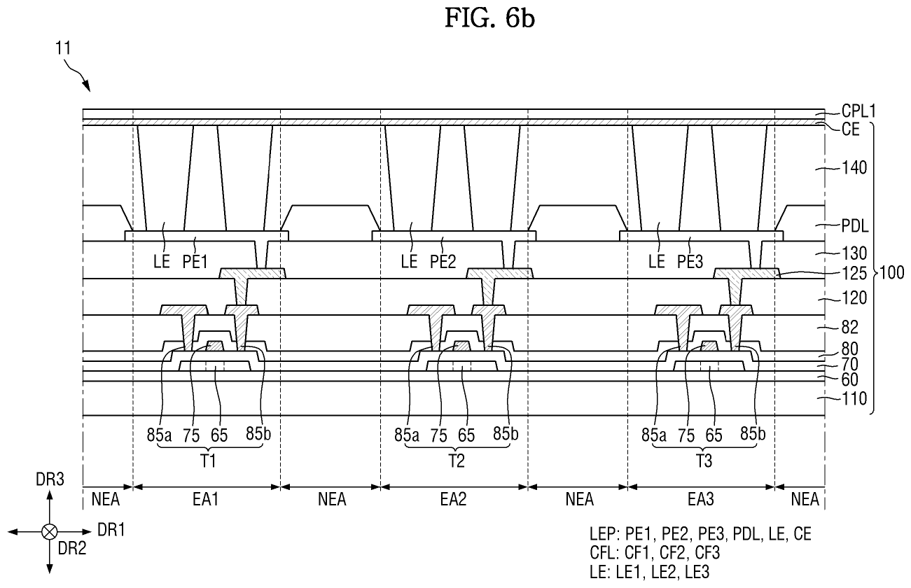

The driving transistor DTR and the first and second transistors STR1 and STR2 may be formed as thin film transistors. Furthermore, while FIG. 6 describes the driving transistor DTR and the first and second switching transistors STR1 and STR2 as being N-type MOSFET (metal oxide semiconductor field effect transistors), it is not limited to thereto. That is, the driving transistor DTR and the first and second switching transistors STR1 and STR2 may be P-type MOSFET, or some may be N-type MOSFET, and others may be P-type MOSFET.

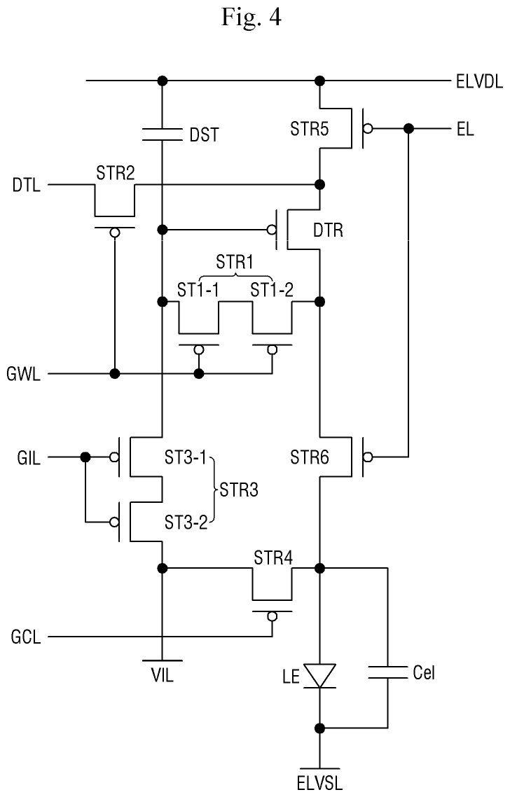

FIG. 4 is an equivalent circuit diagram of one-pixel of a display device according to one or more other embodiments.

Referring to FIG. 4, the first electrode of the light-emitting element LE may be connected to the first electrode of the fourth transistor STR4 and the second electrode of the sixth transistor STR6, and the second electrode of the light-emitting element LE may be connected to the second power supply line ELVSL. A parasitic capacitance Cel may be formed between the first electrode and the second electrode of the light-emitting element LE.

Each pixel PX includes the driving transistor DTR, switch elements, and the capacitor CST. The switch elements include first to sixth transistors STR1, STR2, STR3, STR4, STR5, and STR6.

The driving transistor DTR includes the gate electrode, the first electrode, and the second electrode. The driving transistor DTR controls the drain-to-source current (hereinafter referred to as the “driving current”) flowing between the first and second electrodes based on the data voltage applied to the gate electrode.

The capacitor CST is formed between the second electrode of the driving transistor DTR and the second power supply line ELVSL. One electrode of the capacitor CST may be connected to the second electrode of the driving transistor DTR, and the other electrode may be connected to the second power supply line ELVSL.

When the first electrode of each of the first to sixth transistors STR1, STR2, STR3, STR4, STR5, and STR6 and the driving transistor DTR is the source electrode, the second electrode may be the drain electrode. Alternatively, if the first electrode of each of the first to sixth transistors STR1, STR2, STR3, STR4, STR5, and STR6 and the driving transistor DTR is the drain electrode, the second electrode may be the source electrode.

An active layer of each of the first to sixth transistors STR1, STR2, STR3, STR4, STR5, and STR6 and the driving transistor DTR may be formed from any of poly silicon, amorphous silicon, and oxide semiconductors. When the semiconductor layer of each of the first through sixth transistors STR1, STR2, STR3, STR4, STR5, and STR6 and the driving transistor DTR is formed from poly silicon, the process for forming the semiconductor layer may be a low temperature poly silicon (LTPS) process.

In addition, in FIG. 4, the first to sixth transistors STR1, STR2, STR3, STR4, STR5, and STR6 and the driving transistor DTR are described centering on the P-type MOSFET (Metal Oxide Semiconductor Field Effect Transistor), but are not limited thereto, and may be formed as the N-type MOSFET.

Further, the first power supply voltage of the first power supply line ELVDL, the second power supply voltage of the second power supply line ELVSL, and the third power supply voltage of the third power supply line VIL may be set by considering the characteristics of the driving transistor DTR, the characteristics of the light-emitting element LE, and/or the like.

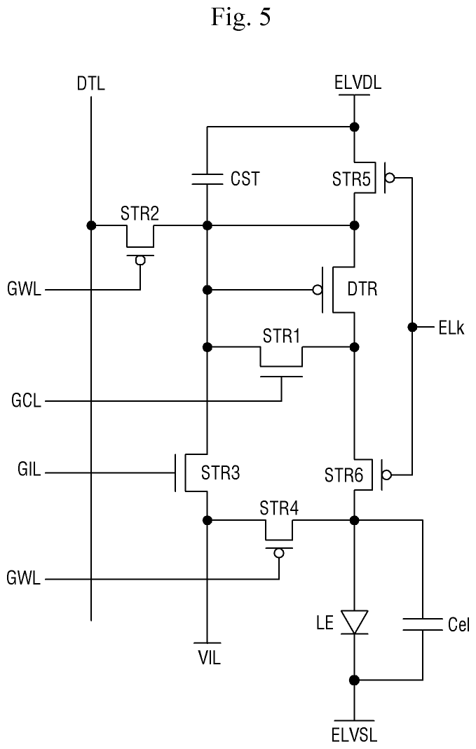

FIG. 5 is an equivalent circuit diagram of one-pixel of a display device according to one or more other embodiments.

The one or more embodiments corresponding to FIG. 5 differs from the one or more embodiments corresponding to FIG. 4 in that the driving transistor DTR, the second transistor STR2, the fourth transistor STR4, the fifth transistor STR5, and the sixth transistor STR6 are formed as the P-type MOSFET, and the first transistor STR1 and the third transistor STR3 are formed as the N-type MOSFET.

Referring to FIG. 5, the active layer of each of the driving transistor DTR, second transistor STR2, fourth transistor STR4, fifth transistor STR5, and sixth transistor STR6 formed as the P-type MOSFET may be formed of polysilicon, and the active layer of each of the first transistor STR1 and third transistor STR3 formed as the N-type MOSFET may be formed of an oxide semiconductor.

FIG. 5 differs from the one or more embodiments corresponding to FIG. 4 in that the gate electrode of the second transistor STR2 and the gate electrode of the fourth transistor STR4 are connected to the write scan line GWL, and the gate electrode of the first transistor ST1 is connected to the control scan ling GCL. Also, in FIG. 5, the first transistor STR1 and the third transistor STR3 are formed as the N-type MOSFET, so that the scan signal of the gate high voltage may be applied to the control scan line GCL and the initialization scan line GIL. On the other hand, because the second transistor STR2, the fourth transistor STR4, the fifth transistor STR5, and the sixth transistor STR6 are formed as the P-type MOSFET, the scan signal with a gate low voltage may be applied to the write scan wire GWL and the light-emitting element LE.

It should be noted that the equivalent circuit diagram of a pixel according to one or more embodiments of the present disclosure described above is not limited to that shown in FIGS. 3 to 5. The equivalent circuit diagram of a pixel according to one or more embodiments of the present disclosure may be formed by other known circuit structures that may be employed by those skilled in the art other than the embodiments shown in FIGS. 3 to 5.

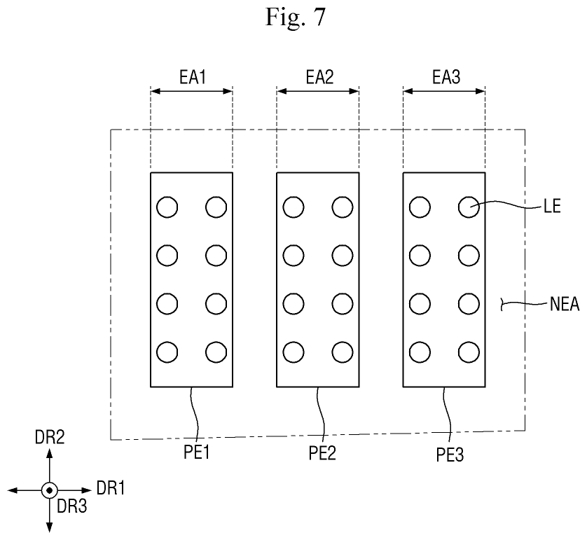

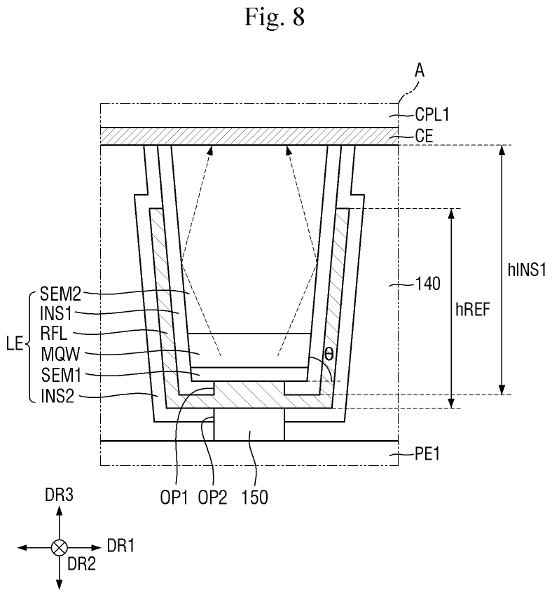

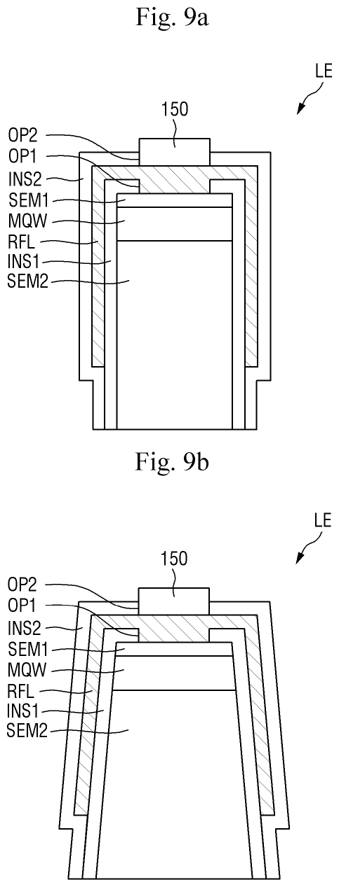

FIG. 6a is a schematic cross-sectional view of a display device according to one or more embodiments, and FIG. 6b is a schematic cross-sectional view of a display device according to one or more other embodiments. FIG. 7 is a plan view illustrating light-emitting areas of a display device according to one or more embodiments. FIG. 8 is an enlarged view of area A of FIG. 6a. FIGS. 9a and 9b are cross-sectional views schematically illustrating a structure of a light-emitting element according to one or more embodiments.

Referring to FIG. 6, the display device 10 may include a display substrate 100, a wavelength control unit 200, and a color filter layer CFL located on the display substrate 100.

The display substrate 100 may include a substrate 110, and a light-emitting element part LEP located on the substrate 110. The substrate 110 may be an insulating substrate. The substrate 110 may include a transparent material. For example, the substrate 110 may include a transparent insulating material, such as glass, quartz, or the like. The substrate 110 may be a rigid substrate. However, the substrate 110 is not limited thereto and may include a plastic, such as polyimide, or the like. Also, the substrate 110 may have flexible characteristics that allow the substrate to be warped, bent, folded, or rolled. A plurality of emitting areas EA1, EA2, and EA3 and non-emitting areas NEA may be defined on the substrate 110.

Switching elements T1, T2, and T3 may be located on the substrate 110. In one or more embodiments, the first switching element T1 may be located in the first light-emitting area EA1 of the substrate 110, the second switching element T2 may be located in the second light-emitting area EA2, and the third switching element T3 may be located in the third light-emitting area EA3. However, it is not limited to this, and at least one of the first switching element T1, the second switching element T2, or the third switching element T3 may be located in the non-emitting area NEA in other embodiments.

In one or more embodiments, the first switching element T1, the second switching element T2, and the third switching element T3 may each be a thin film transistor including an amorphous silicon, polysilicon, or oxide semiconductor. In one or more embodiments, there may be a plurality of signal lines (e.g., gate lines, data lines, power supply lines, etc.) further located on the substrate 110 that carry signals to each switching element.

Each switching element T1, T2, and T3 may include a semiconductor layer 65, a gate electrode 75, a source electrode 85a, and a drain electrode 85b. For example, a buffer layer 60 may be located on the substrate 110. The buffer layer 60 may cover a front side of the substrate 110. The buffer layer 60 may include a silicon nitride, a silicon oxide, or a silicon oxynitride, and may be a single layer or a double layer.

The semiconductor layer 65 may be located on the buffer layer 60. The semiconductor layer 65 may form a channel of each of the switching elements T1, T2, and T3. The semiconductor layer 65 may include amorphous silicon, polycrystalline silicon, or an oxide semiconductor. For example, the oxide semiconductor may include a binary compound (ABx), a ternary compound (ABxCy), or a tetracyclic compound (ABxCyDz) containing indium, zinc, gallium, tin, titanium, aluminum, hafnium (Hf), zirconium (Zr), magnesium (Mg), and/or the like. In one or more embodiments, the semiconductor layer 65 may include indium tin zinc oxide (IGZO).

A gate-insulating layer 70 may be located on the semiconductor layer 65. The gate-insulating layer 70 may include a silicon compound, a metal oxide, or the like. For example, the gate-insulating layer 70 may include a silicon oxide, a silicon nitride, a silicon oxynitride, an aluminum oxide, a tantalum oxide, a hafnium oxide, a zirconium oxide, a titanium oxide, and/or the like. In one or more embodiments, the gate-insulating layer 70 may include a silicon oxide.

The gate electrode 75 may be located on the gate-insulating layer 70. The gate electrode 75 may overlap the semiconductor layer 65. The gate electrode 75 may include a conductive material. The gate electrode 75 may include a metal oxide, such as ITO, IZO, ITZO, In₂O₃, or a metal, such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be formed of a Cu/Ti double layer in which an upper layer of copper is stacked on a lower layer of titanium but is not limited thereto.

A first interlayer insulating layer 80 and a second interlayer insulating layer 82 may be located on the gate electrode 75. The first interlayer insulating layer 80 may be directly located on the gate electrode 75, and the second interlayer insulating layer 82 may be directly located on the first interlayer insulating layer 80. The first interlayer insulating layer 80 and the second interlayer insulating layer 82 each may include an inorganic insulating material, such as a silicon oxide, a silicon nitride, a silicon oxynitride, a hafnium oxide, an aluminum oxide, a titanium oxide, a tantalum oxide, a zinc oxide, and/or the like. However, it is not limited thereto, and the second interlayer insulating layer 82 may include an organic insulating material capable of flattening a lower step.

The source electrode 85a and a drain electrode 85b may be located on the second interlayer insulating layer 82. The source electrode 85a and the drain electrode 85b may be connected to the semiconductor layer 65 through contact holes penetrating the first interlayer insulating layer 80, the second interlayer insulating layer 82, and the gate-insulating layer 70, respectively. The source electrode 85a and the drain electrode 85b may include metal oxides, such as ITO, IZO, ITZO, In₂O₃, or metals, such as copper (Cu), titanium (Ti), aluminum (Al), molybdenum (Mo), tantalum (Ta), calcium (Ca), chromium (Cr), magnesium (Mg), and/or nickel (Ni). For example, the source electrode 85a and the drain electrode 85b may be formed of a Cu/Ti double layer in which an upper layer of copper is stacked on a lower layer of titanium but is not limited thereto.

A first planarization layer 120 may be located on the first switching element T1, the second switching element T2, and the third switching element T3. The first planarization layer 120 may include an organic material. For example, the first planarization layer 120 may include an acrylic resin, an epoxy resin, an imide resin, an ester resin, or the like. In one or more embodiments, the first planarization layer 120 may include a positive photosensitive material or a negative photosensitive material.

A pixel connection electrode 125 may be located on the first planarization layer 120. The pixel connection electrode 125 is corresponds to each of the first switching element T1, the second switching element T2, and the third switching element T3, and may be electrically connected to them. The pixel connection electrode 125 may connect pixel electrodes PE1, PE2, and PE3, to be described later, to the switching elements T1, T2, and T3 described above. The pixel connection electrode 125 may contact the switching elements T1, T2, and T3 through a contact hole penetrating the first planarization layer 120.

A second planarization layer 130 may be located on the first planarization layer 120 and the pixel connection electrode 125. The second planarization layer 130 flattens the lower step and may include the same material as the first planarization layer 120 described above.

A light-emitting element part LEP may be located on the second planarization layer 130. The light-emitting element part LEP may include a plurality of pixel electrodes PE1, PE2, and PE3, a plurality of light-emitting elements LE, and a common electrode CE. Also, the light-emitting element part LEP may further include a pixel-defining layer PDL and an organic layer 140 that partition each of the light-emitting areas EA1, EA2, and EA3.

The plurality of pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as the first electrode of the light-emitting element LE, and may be the anode electrode or the cathode electrode. The first pixel electrode PE1 may be located in the light-emitting area EA1, the second pixel electrode PE2 may be located in the second light-emitting area EA2, and the third pixel electrode PE3 may be located in the third light-emitting area EA3. In one or more embodiments, the first pixel electrode PE1 may fully overlap the first light-emitting area EA1, the second pixel electrode PE2 may fully overlap the second light-emitting area EA2, and the third pixel electrode PE3 may fully overlap the third light-emitting area EA3.

Each of the pixel electrodes PE1, PE2, and PE3 may be directly connected to the pixel connection electrode 125 through the contact hole penetrating the second planarization layer 130, and may be respectively electrically connected to the switching elements T1, T2, and T3 through the pixel connection electrode 125. The first pixel electrode PE1, the second pixel electrode PE2, and the third pixel electrode PE3 may include metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Also, the first pixel electrode PE1, the second pixel electrode PE2, and the third pixel electrode PE3 may have a multilayer structure in which two or more metal layers are stacked. For example, the first pixel electrode PE1, the second pixel electrode PE2, and the third pixel electrode PE3 may have a two-layer structure in which a copper layer is stacked on a titanium layer, but is not limited thereto.

The plurality of light-emitting elements LE may be located on each of the first pixel electrode PE1, the second pixel electrode PE2, and the third pixel electrode PE3.

As shown in FIGS. 6a, 6b, and 7, the light-emitting elements LE may be located in the first light-emitting area EA1, the second light-emitting area EA2, and the third light-emitting area EA3, respectively. The light-emitting element LE may be a vertical light-emitting diode element extending lengthwise in the third direction DR3. That is, the length of the light-emitting element LE in the third direction DR3 may be longer than that in the horizontal direction. The length in the horizontal direction refers to the length of the first direction DR1 or the length of the second direction DR2. A detailed description of the light-emitting element LE will be described later.

The organic layer 140 may be located on the plurality of pixel electrodes PE1, PE2, and PE3 and the pixel-defining layer PDL. The organic layer 140 may flatten a lower step so that the common electrode CE may be formed, the common electrode CE being described further below. The organic layer 140 may be formed to a height (e.g., predetermined height) so that at least a portion of the plurality of light-emitting elements LE may protrude above the organic layer 140. That is, the height of the organic layer 140 based on the top surface of the first pixel electrode PE1 may be less than the height of the light-emitting element LE.

The organic layer 140 may include the organic material to planarize the lower step. For example, the organic layer 140 may include a polyacrylates resin, an epoxy resin, a phenolic resin, a polyamides resin, or a polyimides rein, unsaturated polyester resin, poly phenylenethers resin, polyphenylenesulfides resin, or benzocyclobutene (BCB).

The common electrode CE may be located on the organic layer 140 and the plurality of light-emitting elements LE. In detail, the common electrode CE is located on one surface of the substrate 110 on which the light-emitting element LE is formed, and may be located in the entire display area DPA. The common electrode CE is located overlapping each of the light-emitting areas EA1, EA2, and EA3 in the display area DPA, and may have a relatively thin thickness so that light may be emitted.

The common electrode CE may be directly located on upper and side surfaces of the plurality of light-emitting elements LE. For example, the common electrode CE may contact the second semiconductor layer SEM2, which is the upper surface of the light-emitting element LE, and may directly contact the reflective layer RF, which is the side surface of the light-emitting element LE. The common electrode CE may be a common layer covering the plurality of light-emitting elements LE and connecting the plurality of light-emitting elements LE in common.

Because the common electrode CE is entirely located on the substrate 110 (e.g., is located over a substantial entirety of the substrate 110), and because a common voltage is applied thereto, the common electrode CE may include a material having low resistance. Also, the common electrode CE may be formed to have a thin thickness to suitably transmit light. For example, the common electrode CE may include a low-resistance metal material, such as aluminum (Al), silver (Ag), or copper (Cu), or a metal oxide, such as ITO, IZO, or ITZO. The common electrode CE may have a thickness of about 10 Å to about 200 Å but is not limited thereto.

The light-emitting elements LE may receive a pixel voltage or an anode voltage from each of the pixel electrodes PE1, PE2, and PE3 and may receive a common voltage through the common electrode CE. The light-emitting elements LE may emit light with a luminance (e.g., predetermined luminance) according to a voltage difference between the pixel voltage and the common voltage. In one or more embodiments, it is possible to eliminate the disadvantages of the organic light-emitting diode, which may be vulnerable to external moisture or oxygen, and to improve the lifespan and reliability by disposing a plurality of light-emitting elements LE, that is, inorganic light-emitting diodes, on the pixel electrodes PE1, PE2, and PE3.

As shown in FIG. 7, the light-emitting elements LE may be located on each of the pixel electrodes PE1, PE2, and PE3. The light-emitting elements LE may be regularly arranged according to a certain rule. For example, the light-emitting elements LE may be spaced apart from each other at regular intervals. However, it is not limited thereto, and the light-emitting elements LE may be irregularly arranged. Referring to FIGS. 6a, 6b, and 7, two light-emitting elements LE are exemplified for each of the pixel electrodes PE1, PE2, and PE3, but the number of light-emitting elements LE located on each of the pixel electrodes PE1, PE2, and PE3 is not limited.

Each of the light-emitting elements LE may be substantially located on each of the pixel electrodes PE1, PE2, and PE3. However, the present disclosure is not limited thereto, and some light-emitting elements LE may be located between each pixel electrode PE1, PE2, and PE3, may be partially located across any of the pixel electrodes, or may not be located on any pixel electrodes.

Meanwhile, a first capping layer CPL1 may be located on the substrate 110 on which the common electrode CE is located. The first capping layer CPL1 may be directly located on the common electrode CE. The first capping layer CPL1 serves to protect components located therebelow (e.g., the light-emitting elements LE and the common electrode CE) from moisture or debris by covering them.

The first capping layer CPL1 may include an inorganic material. For example, the first capping layer CPL1 may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxide. Meanwhile, although the drawing illustrates that the first capping layer CPL1 is formed of one layer, it is not limited thereto. For example, the first capping layer CPL1 may be formed as multiple layers stacked with alternating inorganic layers including at least one of the materials exemplified as materials that the first capping layer CPL1 may include. The thickness of the first capping layer CPL1 may range from about 0.05 μm to about 2 um, but is not limited thereto.

Meanwhile, referring to FIG. 6a, the wavelength control unit 200 may be located on the light-emitting element part LEP. The wavelength control unit 200 may include a first wavelength conversion layer WCL1, a second wavelength conversion layer WCL2, and a light-transmitting layer TPL. Also, the wavelength control unit 200 may further include a bank layer BNL.

The bank layer BNL is located on the first capping layer CPL1, and may partition a plurality of light-emitting areas EA1, EA2, and EA3. The bank layer BNL may extend in the first and second directions DR1 and DR2, and may be formed in a lattice pattern throughout the display area DPA. Also, the bank layer BNL does not overlap with the plurality of emitting areas EA1, EA2, and EA3, and may overlap with the non-emitting area NEA.

The bank layer BNL may serve to provide a space in which the first wavelength conversion layer WCL1, the second wavelength conversion layer WCL2, and the light-transmitting layer TPL are formed. To this end, the bank layer BNL may have a thickness of about 1 μm to about 10 μm. The bank layer BNL may include an organic insulating material to be formed with a large thickness. The organic insulating material may include, for example, an epoxy-based resin, an acrylic-based resin, a cardo-based resin, or an imide-based resin.

In one or more embodiments, the bank layer BNL may further include a light-blocking material, and may include a dye or pigment having light-blocking properties. For example, the bank layer BNL may be a black matrix. External light incident from the outside of the display device 10 may cause a problem of distorting the color gamut of the wavelength control unit 200. Color distortion due to reflection of external light may be reduced by having the bank layer BNL including the light-blocking material in the wavelength control unit 200. In addition, the bank layer BNL including the light-blocking material may reduce or prevent light penetrating between adjacent light-emitting areas, and thus may reduce or prevent color mixing, thereby further improving color reproducibility.

The first wavelength conversion layer WCL1, the second wavelength conversion layer WCL2, and the light-transmitting layer TPL may be located on the emitting areas EA1, EA2, and EA3. The first wavelength conversion layer WCL1 and the second wavelength conversion layer WCL2 may convert or shift the peak wavelength of incident light into another corresponding peak wavelength, and may emit the light. The first wavelength conversion layer WCL1 converts blue light emitted from the light-emitting element LE into red light, and the second wavelength conversion layer WCL2 converts blue light into green light. The light transmission layer TP may transmit blue light without conversion.

The first wavelength conversion layer WCL1, the second wavelength conversion layer WCL2, and the light-transmitting layer TPL may be located in each of the light-emitting areas EA1, EA2, and EA3 partitioned by the bank layer BNL, and may be arranged spaced apart from each other. That is, the first wavelength conversion layer WCL1, the second wavelength conversion layer WCL2, and the light-transmitting layer TPL may be formed in a dot-shaped island pattern spaced apart from each other.

The first wavelength conversion layer WCL1 may overlap the first emitting area EA1. The first wavelength conversion layer WCL1 may convert or shift a peak wavelength of incident light into light having another corresponding peak wavelength, and may emit the light. In one or more embodiments, the first wavelength conversion layer WCL1 may convert blue light emitted from the light-emitting element LE of the first light-emitting area EA1 into red light having a single peak wavelength in the range of about 610 nm to about 650 nm, and may emit the red light.

The first wavelength conversion layer WCL1 may include a first base resin BRS1, first wavelength conversion particles WCP1, and may include scatterers SCP dispersed in the first base resin BRS1. The first base resin BRS1 may include a light-transmitting organic material. For example, the first base resin BRS1 may include an epoxy-based resin, an acrylic-based resin, a cardo-based resin, or an imide-based resin.

The first wavelength conversion particle WCP1 may convert blue light incident from the light-emitting element LE into red light. For example, the first wavelength conversion particle WCP1 may convert light in a blue wavelength band into light in a red wavelength band. The first wavelength conversion particle WCP1 may be a quantum dot (QD), a quantum rod, a fluorescent material, or a phosphorescent material. For example, the quantum dot may be a particulate material that emits a corresponding color while electrons transition from a conduction band to a valence band.

The quantum dots may be semiconductor nanocrystalline materials. Depending on the composition and size thereof, the quantum dot may have a corresponding bandgap to absorb light, and may emit light with a unique wavelength. Examples of the semiconductor nanocrystals of the quantum dots include IV group nanocrystals, II-VI group compound nanocrystals, III-V group compound nanocrystals, IV-VI group nanocrystals, or combinations thereof.

The group II-VI compound is a binary compound selected from the group comprising CdSe, CdTe, ZnS, ZnSe, ZnTe, ZnO, HgS, HgSe, HgTe, MgSe, MgS, or mixtures thereof; InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or ternary compounds selected from the group comprising mixtures thereof; or a quaternary compound selected from the group comprising HgZnTeS, CdZnSeS, CdZnSeTe, CdZnSTe, CdHgSeS, CdHgSeTe, CdHgSTe, HgZnSeS, HgZnSeTe, HgZnSTe, or mixtures thereof.

The group III-V compound is a binary compound selected from the group comprising GaN, GaP, GaAs, GaSb, AlN, AlP, AlAs, AlSb, InN, InP, InAs, InSb, or mixtures thereof; a ternary compound selected from the group comprising GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, or mixtures thereof; or a quaternary compound selected from the group comprising GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures thereof.

The group IV-VI compounds may be selected from the group comprising binary compounds selected from the group comprising SnS, SnSe, SnTe, PbS, PbSe, PbTe, or mixtures thereof; ternary compounds selected from the group comprising SnSeS, SnSeTe, SnSTe, PbSeS, PbSeTe, PbSTe, SnPbS, SnPbSe, SnPbTe, or mixtures thereof; or a quaternary compound selected from the group comprising SnPbSSe, SnPbSeTe, SnPbSTe, or mixtures thereof. The group IV element may be selected from the group comprising Si, Ge, or mixtures thereof. The group IV compound may be a binary compound selected from the group comprising SiC, SiGe, or mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In one or more embodiments, the quantum dot may have a core-shell structure including a core including a nanocrystal as described above and a shell surrounding the core. The shell of the quantum dot may act as a protective layer to reduce or prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, or combinations thereof.

For example, the oxides of said metals or non-metals may be exemplified by binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds, such as MgAl₂O₄, CoFe₂O₄, NiFe₂O₄, CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. but are not limited thereto.

The scatterer SCP may scatter the light of the light-emitting element LE in a random direction. The scatterer SCP may have a refractive index different from that of the first base resin BRS1, and may form an optical interface with the first base resin BRS1. For example, the scatterer SCP may be a light-scattering particle. The scatterer SCP is not particularly limited to any material capable of scattering at least a portion of the transmitted light, but may be, for example, metal oxide particles or organic particles. Examples of the metal oxide include titanium oxide (TiO₂), zirconium oxide (ZrO₂), aluminum oxide (Al₂O₃), indium oxide (In₂O₃), zinc oxide (ZnO), tin oxide (SnO₂), and/or the like, and examples of organic particle materials include acrylic resins or urethane resins. The scatterer SCP may scatter light in the random direction regardless of the incident direction of incident light without substantially converting the wavelength of light.

The second wavelength conversion layer WCL2 may overlap the second emission area EA2. The second wavelength conversion layer WCL2 may convert or shift the peak wavelength of incident light into light having another corresponding peak wavelength, and may emit the light. In one or more embodiments, the second wavelength conversion layer WCL2 may convert blue light emitted from the light-emitting element LE of the second light-emitting area EA2 into green light having the peak wavelength in a range of about 510 nm to about 550 nm, and may emit the green light.

The second wavelength conversion layer WCL2 may include a second base resin BRS2 and second wavelength conversion particles WCP2, and may include scatterers SCP dispersed in the second base resin BRS2.

The second base resin BRS2 may be made of a material having relatively high light transmittance, and may be made of the same material as the first base resin BRS1, or may include at least one of the exemplified materials as constituent materials thereof.

The second wavelength conversion particle WCP2 may convert or shift the peak wavelength of incident light to another corresponding peak wavelength. In one or more embodiments, the second wavelength conversion particle WCP2 may convert blue light provided from the light-emitting element LE into green light having a peak wavelength in a range of about 510 nm to about 550 nm, and may emit the green light. Examples of the second wavelength conversion particle WCP2 include quantum dots, quantum rods, or phosphors. Further description of the second wavelength conversion particle WCP2 is substantially the same as, or similar to, that described above in the description of the first wavelength conversion particle WCP1, and thus will not be repeated.

The light-transmitting layer TPL may overlap the third light-emitting area EA3. The light-transmitting layer TPL may transmit incident light. The light-transmitting layer TPL may transmit blue light emitted from the light-emitting element LE located in the third light-emitting area EA3 as is. The light-transmitting layer TPL may include a third base resin BRS3, and scatterers SCP dispersed in the third base resin BRS3. Because the third base resin BRS3 is substantially the same as, or similar to, the first base resin BRS3 described above, a description thereof will not be repeated.

The light transmitted the wavelength control unit 200 may implement full color by passing through the color filter layer CFL, which will be described later.

The wavelength control unit 200 may further include a second capping layer CPL2. The second capping layer CPL2 covers the first wavelength conversion layer WCL1, the second wavelength conversion layer WCL2, the light-transmitting layer TPL, and the bank layer BNL located thereunder to protect them from moisture or foreign matter. The second capping layer CPL2 may include an inorganic material, and may include a material that is substantially the same as, or similar to, that of the first capping layer CPL1 described above.

A first color filter CF1, a second color filter CF2, and a third color filter CF3 may be located on the second capping layer CPL2. The first color filter CF1 is located in the first light-emitting area EA1, the second color filter CF2 is located in the second light-emitting area EA2, and the third color filter CF3 is located in the third light-emitting area EA3.

The first color filter CF1, the second color filter CF2, and the third color filter CF3 may include colorants, such as dyes or pigments that absorb wavelengths other than the corresponding color wavelengths. The first color filter CF1 may selectively transmit red light, and may block or absorb blue and green light. The second color filter CF2 may selectively transmit green light, and may block or absorb blue and red light. The third color filter CF3 may selectively transmit blue light, and may block or absorb red and green light. For example, the first color filter CF1 may be a red color filter, the second color filter CF2 may be a green color filter, and the third color filter CF3 may be a blue color filter.

In one or more embodiments, light incident on the first color filter CF1 may be light converted to red light by the first wavelength conversion layer WCL1, and light incident on the second color filter CF2 may be light converted into green light by the second wavelength conversion layer WCL2, and light incident on the third color filter CF3 may be blue light transmitted through the light-transmitting layer TPL. As a result, the red light transmitted through the first color filter CF1, the green light transmitted through the second color filter CF2, and the blue light transmitted through the third color filter CF3 may be emitted onto the upper of the substrate 110 to achieve full color.

The first color filter CF1, the second color filter CF2, and the third color filter CF3 may absorb some of the light introduced from the outside of the display device 10 to reduce reflected light caused by external light. Accordingly, the first color filter CF1, the second color filter CF2, and the third color filter CF3 may reduce or prevent color distortion due to external light reflection.

In addition, the first color filter CF1 is located in the non-emitting area NEA, and at least one of the second color filter CF2 and the third color filter CF3 may overlap each other. That is, the first color filter CF1, the second color filter CF2, and the third color filter CF3 may be located in the non-emitting area NEA.

Accordingly, light emission from the display device may be blocked in the non-emitting area NEA, and reflection of external light may be suppressed. Each color filter CF1, CF2, and CF3 blocks the emission of light of a color that is other than the corresponding color of each light-emitting area EA1, EA2, and EA3, and accordingly, light of red, green, and blue colors may all be blocked in the non-emitting area NEA. However, the present disclosure is not limited thereto, and a light-absorbing member including a light-absorbing material of a visible light wavelength band may be located in the non-emitting area NEA.

An overcoat layer OC may be located on the color filter layer CFL. The overcoat layer OC may be directly located on the color filter layer CFL. The overcoat layer OC may be entirely located in the display area DPA, and may have a flat surface. The overcoat layer OC may flatten a step formed by the lower color filter layer CFL. The overcoat layer OC may include the light-transmitting organic material.

Referring to FIG. 6b, in one or more embodiments, the first light-emitting element LE1 located in the first light-emitting area EA1 may emit a first light of blue color, the second light-emitting element LE2 located in the second light-emitting area EA2 may emit a second light of red color, and the third light-emitting element LE3 located in the third light-emitting area LE3 may emit a third light of green color. In this way, when the light-emitting elements located in different light-emitting areas may emit light of different wavelengths, the wavelength control unit 200 and the color filter layer CFL described with reference to FIG. 6a may be omitted.

Meanwhile, in FIG. 8, the light-emitting element LE located on the first pixel electrode PE1 will be described as an example.

Referring to FIGS. 8, 9a, and 9b, the light-emitting element LE is a particulate element, and may have a rod or cylindrical shape having an aspect ratio (e.g., predetermined aspect ratio), or a combination shape of a pyramid shape and a rod shape. The light-emitting element LE may have a size of a nanometer scale (1 nm or more and less than 1 μm) or a micrometer scale (1 μm or more and less than 1 mm). In one or more embodiments, both the diameter and the length of the light-emitting element LE may have a nanometer scale size, or both may have a micrometer scale size. In some other embodiments, the diameter of the light-emitting element LE may have a nanometer scale while the length of the light-emitting element LE may have a micrometer scale. In some embodiments, some of the light-emitting elements LE may have diameters and/or lengths on the nanometer scale, while other portions of the light-emitting elements LE may have diameters and/or lengths on the micrometer scale.

In one or more embodiments, the light-emitting element LE may be an inorganic light-emitting diode. In detail, the light-emitting element LE may include a semiconductor layer doped with any conductive (eg, p-type or n-type) impurity. The semiconductor layer may receive an electrical signal applied from an external power source, and may emit light in a corresponding wavelength range.

The light-emitting element LE according to one or more embodiments may include a first semiconductor layer SEM1, an active layer MQW, and a second semiconductor layer SEM2 sequentially stacked in the longitudinal direction.

In addition, the light-emitting element LE may further include the first semiconductor layer SEM1, the active layer MQW, and a first insulating layer INS1 surrounding an outer surface of the second semiconductor layer SEM2, a reflective layer RFL located on the first insulating layer INS1, and a second insulating layer INS2 surrounding the reflective layer RFL.

The first semiconductor layer SEM1 may be a p-type semiconductor and may include a semiconductor material having a chemical formula of AlxGayIn1−x−yN (0≤x≤1, 0≤y≤1, 0≤x+y≤1). For example, the first semiconductor layer SEM1 may be any one or more of p-type doped AlGaInN, GaN, AlGaN, InGaN, AlN, and/or InN. The first semiconductor layer SEM1 may be doped with a p-type dopant, and the p-type dopant may be Mg, Zn, Ca, Ba, or the like. For example, the first semiconductor layer SEM1 may be p-GaN doped with p-type Mg. The thickness of the first semiconductor layer SEM1 may range from about 30 nm to about 200 nm, but is not limited thereto.

The active layer MQW may be located on the first semiconductor layer SEM1. The active layer MQW may emit light by combining electron-hole pairs according to electrical signals applied through the first semiconductor layer SEM1 and the second semiconductor layer SEM2. The active layer MQW may emit light in a blue wavelength band having a central wavelength range of about 450 nm to about 495 nm.

The active layer MQW may include a single or multiple quantum well structure. If the active layer includes a material with a multi-quantum well structure, the active layer may be a stacked structure with a plurality of well layers and a barrier layer alternating with each other. In this case, the well layer may be formed of InGaN and the barrier layer may be formed of GaN or AlGaN, but is not limited thereto. The thickness of the well layer may be about 1 nm to about 4 nm, and the thickness of the barrier layer may be about 3 nm to about 10 nm.

Alternatively, the active layer MQW may have a structure in which a semiconductor material having a large band gap energy and a semiconductor material having a small band gap energy are alternately stacked with each other and may include other Group 3 to Group 5 semiconductor materials depending on the wavelength band of the emitted light. Light emitted from the active layer MQW is not limited to blue light, and, according to circumstances, light in a green wavelength band or light in a red wavelength band may be emitted. In one or more embodiments, when indium is included among the semiconductor materials included in the active layer MQW, the color of emitted light may vary according to the amount of indium.

An electron-blocking layer may be located between the first semiconductor layer SEM1 and the active layer MQW. The electron-blocking layer may be a layer for suppressing or preventing too many electrons flowing into the active layer MQW. For example, the electron-blocking layer may be p-AlGaN doped with p-type Mg. The thickness of the electron-blocking layer may be about 10 nm to about 50 nm. The electron-blocking layer may be omitted.

The second semiconductor layer SEM2 may be located on the active layer MQW. The second semiconductor layer SEM2 may be the n-type semiconductor.

When the light-emitting element LE emits light in the blue wavelength band, the second semiconductor layer SEM2 may include a semiconductor material having the formula AlxGayIn1−x−yN (0≤x≤1, 0≤y≤1, 0≤x+y≤1). For example, the second semiconductor layer SEM2 may be one or more of n-type doped AlGaInN, GaN, AlGaN, InGaN, AlN, and/or InN. The first semiconductor layer SEM1 may be doped with an n-type dopant, and the n-type dopant may be Si, Ge, Sn, Se, or the like. For example, the second semiconductor layer SEM2 may be n-GaN doped with n-type Si. The length of the second semiconductor layer SEM2 may range from about 500 nm to about 1 μm but is not limited thereto.

A superlattice layer may be located between the active layer MQW and the second semiconductor layer SEM2. The superlattice layer may be a layer for relieving stress between the second semiconductor layer SEM2 and the active layer MQW. For example, the superlattice layer may be formed of InGaN or GaN. The thickness of the superlattice layer may be about 50 nm to about 200 nm. The superlattice layer may be omitted.

The first insulating layer INS1 may surround the light-emitting elements LE. For example, the first insulating layer INS1 may surround outer surfaces of the first semiconductor layer SEM1, the active layer MQW, and the second semiconductor layer SEM2 described above. Here, the outer surface may be an outer circumferential surface, an outer surface, or a side surface. For example, the first insulating layer INS1 may surround at least an outer surface of the active layer MQW, and may extend in one direction in which the light-emitting element LE extends. The first insulating layer INS1 may serve to protect the members. The first insulating layer INS1 may be formed to surround the side surfaces of the members, and may be formed so that at least a portion of the longitudinal ends of the light-emitting element LE are exposed. For example, the first insulating layer INS1 exposes one end of the light-emitting element LE in the longitudinal direction through a first opening OP1. For example, the first semiconductor layer SEM1 of the first insulating layer INS1 may be exposed through the first opening OP1. Also, the first insulating layer INS1 exposes the other end corresponding to one end of the light-emitting element LE in the longitudinal direction. For example, the first insulating layer INS1 exposes the second semiconductor layer SEM2 of the light-emitting element LE.

The first insulating layer INS1 may include materials having insulating properties, for example, inorganic insulating materials, such as silicon oxide (SiOx), silicon nitride (SiNx), silicon oxynitride (SiOxNy), aluminum oxide (AlxOy), aluminum nitride (AlN), and/or the like. The thickness of the insulating layer INS may be about 0.1 μm but is not limited thereto.

In one or more embodiments, the first insulating layer INS1 may be formed of a single layer or multiple layers of materials having insulating properties. The first insulating layer INS1 may reduce or prevent the likelihood of an electrical short circuit that may otherwise occur when the active layer MQW directly contacts an electrode through which an electrical signal is transmitted to the light-emitting element LE. In addition, because the first insulating layer INS1 protects the outer surface of the light-emitting element LE by including the active layer MQW, a decrease in light-emitting efficiency may be reduced or prevented.

Meanwhile, the reflective layer RFL may be located on the first insulating layer INS1 to surround the first semiconductor layer SEM1, the active layer MQW, and the second semiconductor layer SEM2. The reflective layer RFL is located on the first insulating layer INS1 to surround at least the side surface of the active layer MQW. Also, the reflective layer RFL may be arranged to surround a side of the first semiconductor layer SEM1 extending in a direction in which the light-emitting element LE extends from the side of the active layer MQW. In addition, the reflective layer RFL may extend in a direction in which the light-emitting element LE extends from the side of the active layer MQW on the first insulating layer INS1 to enclose a portion of the outer surface of the second semiconductor layer SEM2. In this case, the height hREF of the reflective layer RFL in one direction in which the light-emitting element LE extends is lower than the height hINS1 of the first insulating layer INS1 in one direction. One end of the reflective layer RFL and one end of the first insulating layer INS1 have a step. Accordingly, the reflective layer RFL may expose the first insulating layer INS1 corresponding to at least a portion of the second semiconductor layer SEM2. One end of the reflective layer RFL does not contact the common electrode CE. On the other hand, one end of the first insulating layer INS1 may contact the common electrode CE.

In addition, the reflective layer RFL is located on one surface of the light-emitting element LE and may contact the first semiconductor layer SEM1 through the first opening OP1.

The reflective layer RFL may reflect light emitted from the active layer MQW, and may emit the light to one side of the second semiconductor layer SEM2. The reflective layer RFL exposes an end of the second semiconductor layer SEM2 of the light-emitting element LE.

The reflective layer RFL may include a metal material having conductivity and high light reflectivity. The reflective layer RFL may include, for example, aluminum (Al) or silver (Ag), or an alloy thereof, and may include a single layer or multiple layers thereof. The multiple layers may be, for example, two layers of titanium/copper, two layers of titanium/aluminum, two layers of nickel/aluminum, two layers of silver/aluminum-silicon alloy, and/or the like. The thickness of the reflective layer RFL may range from about 0.5 nm to about 1.0 μm but is not limited thereto.

The second insulating layer INS2 may be located on the reflective layer RFL and the first insulating layer INS1 on which the reflective layer RFL does not surround the outside of the light-emitting element LE. For example, the second insulating layer INS2 is formed to surround (e.g., in plan view) the reflective layer RFL and the side surface of the first insulating layer INS1 on which the reflective layer RFL is not located, but both ends of the light-emitting element LE in the longitudinal direction may be formed, such that at least a portion thereof is exposed. For example, the second insulating layer INS2 exposes one end of the light-emitting element LE in the longitudinal direction through a second opening OP2. The reflective layer RFL may be exposed through the second opening OP2. Also, the second insulating layer INS2 exposes the other end corresponding to one end of the light-emitting element LE in the longitudinal direction through the second opening OP2. The second opening OP2 may have the same width as the first opening OP1 but is not limited thereto. For example, the width of the second opening OP2 may be less than that of the first opening OP1. In addition, the side surface of the first insulating layer INS1 defining the first opening OP1 and the side surface of the second insulating layer INS2 defining the second opening OP2 may be mutually aligned with the first opening OP1.

A connection electrode 150 is located on the reflective layer RFL defined by the second opening OP2. The connection electrode 150 may be formed to protrude beyond the upper surface of the second insulating layer INS2 to the outside of the light-emitting element LE.

The connection electrode 150 may include at least one of gold (Au), copper (Cu), tin (Sn), silver (Ag), aluminum (Al), or titanium (Ti). For example, the connection electrode 150 may include a 9:1 alloy of gold and tin, an 8:2 alloy, or a 7:3 alloy, or may include an alloy of copper, silver, and tin (SAC305).

Referring to FIG. 8, the light-emitting element LE may be located such that one surface of the reflective layer RFL faces the pixel electrode PE1. The connection electrode 150 may serve to transfer a light-emitting signal from the first pixel electrode PE1 to the light-emitting element LE. The connection electrode 150 may be located at the lowermost end of the light-emitting element LE, and may be located farther from the active layer MQW than the reflective layer RFL.

As shown in FIG. 8, an angle θ between the side surface of the light-emitting element LE and the bottom surface of the reflective layer RFL may be about 90 degrees or less. When the side surface of the light-emitting element LE is inclined, the light emitted from the active layer MQW may be reflected from the reflective layer RFL and suitably emitted to the upward. Accordingly, light emission efficiency of the light-emitting element LE may be further improved.

As described above, the light-emitting element LE may include the multi-layered insulating layers INS1 and INS2 to improve luminous efficiency of the light-emitting element LE, and to improve instantaneous afterimage. Also, the light-emitting element LE further includes the reflective layer RFL, but the reflective layer RFL does not contact the common electrode CE. Therefore, when the connection electrode 150 of the light-emitting element LE and the common electrode CE conduct through the reflective layer RFL, the likelihood of an electrical short circuit may be reduced or prevented.

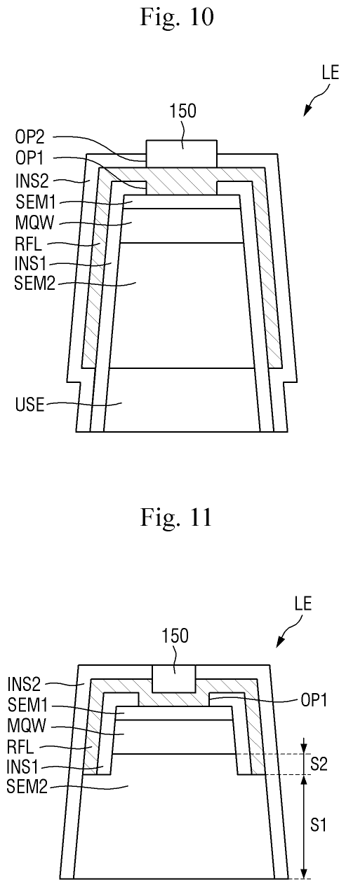

FIG. 10 is a cross-sectional view schematically illustrating a structure of a light-emitting element according to one or more other embodiments.

FIG. 10 is different from the embodiments of FIGS. 8, 9a, and 9b described above in that the light-emitting element LE includes a third semiconductor layer USE, and in that the reflective layer RFL is located on the first insulating layer INS1 to entirely surround the outer surface of the second semiconductor layer SEM2. Hereinafter, descriptions of the same components will be simplified or omitted, and differences will be described in detail.

The light-emitting element LE may include the first semiconductor layer SEM1, the active layer MQW, the second semiconductor layer SEM2, and the third semiconductor layer USE sequentially stacked in the longitudinal direction.

The third semiconductor layer USE may be an undoped semiconductor, and may be a material that is not n-type or p-type doped. In one or more embodiments, the third semiconductor layer USE may be at least one of undoped InAlGaN, GaN, AlGaN, InGaN, AlN, or InN, but is not limited thereto. The thickness of the third semiconductor layer USE may range from about 3 nm to about 200 nm but is not limited thereto.

In addition, the light-emitting element LE may further include the first semiconductor layer SEM1, the active layer MQW, the first insulating layer INS1 that surrounds outer surfaces of the second semiconductor layer SEM2 (e.g., in plan view), the reflective layer RFL located on the first insulating layer INS1, and the second insulating layer INS2 surrounding the reflective layer RFL.

The first insulating layer INS1 may surround the first semiconductor layer SEM1, the active layer MQW, and the second semiconductor layer SEM2.

The reflective layer RFL is located on the first insulating layer INS1 to surround at least the side surface of the active layer MQW. Also, the reflective layer RFL may extend in one direction in which the light-emitting element LE extends from the side surface of the active layer MQW, and may surround the side surface of the first semiconductor layer SEM1. In addition, the reflective layer RFL may be arranged to extend in one direction in which the light-emitting element LE extends from a side of the active layer MQW on the first insulating layer INS1 to surround the outer surface of the second semiconductor layer SEM2. In this case, the reflective layer RFL might not surround the outer surface of the third semiconductor layer USE, but is not limited thereto, and the reflective layer RFL may partially surround the outer surface of the third semiconductor layer USE. However, the reflective layer RFL does not surround the entire outer surface of the third semiconductor layer USE. Therefore, one end of the reflective layer RFL does not contact the common electrode CE. On the other hand, one end of the first insulating layer INS1 may contact the common electrode CE.

In addition, the reflective layer RFL is located on one surface of the light-emitting element LE, and may contact the first semiconductor layer SEM1 through the first opening OP1.

In FIGS. 9a, 9b, and 10, the diameter of the light-emitting element LE is shown, and described as a pyramid shape (e.g., in FIGS. 9b and 10) that widens from the second semiconductor layer SEM2 to the reflective layer RFL, but is not limited thereto. In other words, the sides of the light-emitting element LE may be arranged to have a distance between each other increase from the first semiconductor layer SEM1 to the reflective layer RFL, but is not limited thereto. The side surfaces of the light-emitting elements LE may be rod-shaped, and located side by side.

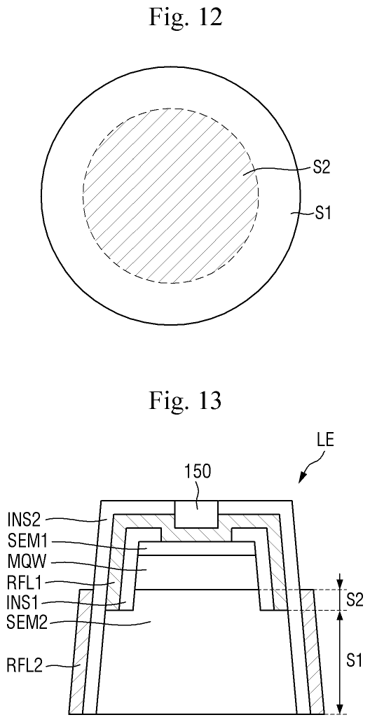

FIG. 11 is a cross-sectional view schematically illustrating a structure of a light-emitting element according to one or more other embodiments. FIG. 12 is a plan view illustrating a second semiconductor layer of a light-emitting element.

FIGS. 11 and 12 differ from the embodiments of FIGS. 8 to 10 described above in that the second semiconductor layer SEM2 of the light-emitting element LE is formed in multiple stages. Hereinafter, descriptions of the same components will be simplified or omitted, and differences will be described in detail.

For example, the second semiconductor layer SEM2 of the light-emitting element LE may include a first portion S1, and a second portion S2 having a smaller diameter than the first portion S1. The first portion S1 forms most of the second semiconductor layer SEM2, and may be a lower portion in the thickness direction of the light-emitting element LE. Also, the second portion S2 of the second semiconductor layer SEM2 is a region surrounded by the first insulating layer INS1 and the reflective layer RFL, and the first portion S1 may be the remaining region of the second semiconductor layer SEM2 except for the second portion S2. The second portion S2 is a part contacting the active layer MQW, and may be an upper part in the thickness direction of the light-emitting element LE. A step is formed between the first portion S1 and the second portion S2 of the second semiconductor layer SEM2, and the step may provide a space in which the first insulating layer INS1 and the reflective layer RFL may be located.

A width or diameter of each of the active layer MQW, the first semiconductor layer SEM1, the second parts S2 of the second semiconductor layer SEM2 may gradually increase. A width or diameter of the first portion S1 of the second semiconductor layer SEM2 may gradually increase. Also, side surfaces of the active layer MQW, the first semiconductor layer SEM1, and the second parts S2 of the second semiconductor layer SEM2 may be aligned and matched with each other. The first portion S1 of the second semiconductor layer SEM2 and the second portion S2 of the second semiconductor layer SEM2 have a step, and the diameter of the second portion S2 of the second semiconductor layer SEM2 may be less than the diameter of the first portion S1 of the second semiconductor layer SEM2.

The first insulating layer INS1 may surround the outer surfaces of the first semiconductor layer SEM1, the active layer MQW, and the second portion S2 of the second semiconductor layer SEM2. The first insulating layer INS1 exposes the first semiconductor layer SEM1 through the first opening OP1.

The reflective layer RFL may surround the outer surfaces of the first semiconductor layer SEM1, the active layer MQW, and the second portion S2 of the second semiconductor layer SEM2 on the first insulating layer INS1. The reflective layer RFL is located on the first insulating layer INS1 having/defining the first opening OP1, and contacts the first semiconductor layer SEM1 through the first opening OP1.

Referring to FIG. 11, the reflective layer RFL surrounds the side surface of the light-emitting element LE and one surface of the light-emitting element LE with the same thickness, but is not limited thereto, and the first opening OP1 may be flattened. That is, the reflective layer RFL may be thicker on the light-emitting element LE in which the first opening OP1 is formed than at the side of the light-emitting element LE.

The second insulating layer INS2 may surround the outer surfaces of the first semiconductor layer SEM1, the active layer MQW, and the second portion S2 of the second semiconductor layer SEM2. Accordingly, the second insulating layer INS2 may surround at least the outer surface of the active layer MQW, thereby protecting the active layer MQW from the outside and reducing or preventing the likelihood of other electrical contact.

The side surface of the reflective layer RFL may be mutually aligned with a side surface of the first portion S1 of the second semiconductor layer SEM2. The reflective layer RFL may surround the outer surfaces of the first semiconductor layer SEM1, the active layer MQW, and the second portion S2 of the second semiconductor layer SEM2. Accordingly, the reflective layer RFL may at least surround the outer surface of the active layer MQW to reflect light emitted from the active layer MQW to the outside, but may be shorter than the extension length of the light-emitting element LE.

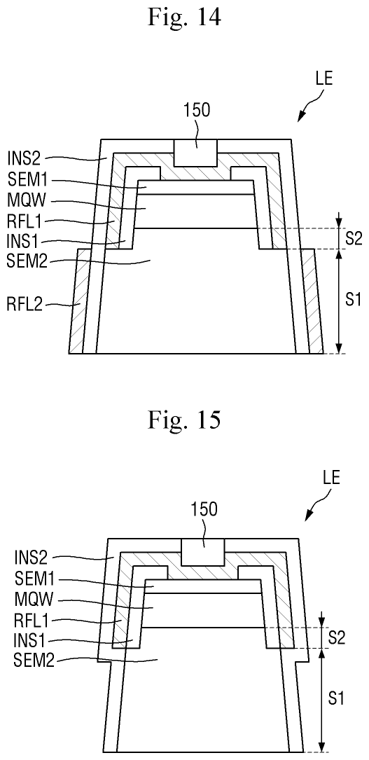

FIGS. 13 and 14 are diagrams illustrating a light-emitting element according to one or more other embodiments.

The one or more embodiments corresponding to FIGS. 13 and 14 differ from the above-described FIG. 11 in further including a metal layer RFL2 located on an outer surface of the second insulating layer INS2. Hereinafter, descriptions of the same components will be simplified or omitted, and differences will be described in detail.

The metal layer RFL2 may include a metal having a high reflectance. The metal layer RFL2 may include the same material as the reflective layer RFL1. The metal layer RFL2 may include a single layer or multiple layers thereof, including, for example, silver (Ag), copper (Cu), aluminum (Al), titanium (Ti), nickel (Ni), and/or the like.

For example, referring to FIGS. 13 and 14, the reflective layer RFL1 may surround the outer surfaces of the first semiconductor layer SEM1, the active layer MQW, and the second portion S2 of the second semiconductor layer SEM2. Also, the metal layer RFL2 may be located on an outer surface of the second insulating layer INS2, and may surround at least an outer surface of the first portion S1 of the second semiconductor layer SEM2.

As shown in FIG. 13, the metal layer RFL2 may surround the outer surface of the second semiconductor layer SEM2 (e.g., including the second portion S2 of the second semiconductor layer SEM2). Thus, the reflective layer RFL1 and the metal layer RFL2 may overlap each other at the second portion S2 of the second semiconductor layer SEM2. Meanwhile, because the second insulating layer INS2 is located between the reflective layer RFL1 and the metal layer RFL2, the reflective layer RFL1 and the metal layer RFL2 do not contact each other.

In addition, as shown in FIG. 14, the metal layer RFL2 may be located on the second insulating layer INS2 to surround the outer surface of the first portion S1 of the second semiconductor layer SEM2 (e.g., without surrounding the outer surface of the second portion S2 of the second semiconductor layer SEM2). Therefore, the metal layer RFL2 does not overlap the reflective layer RFL1.

Referring to FIGS. 13 and 14, the reflective layer RFL1 and the metal layer RFL2 cover the outer surface of the light-emitting element LE to reflect the light emitted from the active layer MQW toward the second semiconductor layer SEM2. Accordingly, light emission efficiency of the light-emitting element LE may be improved.

FIG. 15 is a diagram illustrating a light-emitting element according to one or more other embodiments.

The one or more embodiments corresponding to FIG. 15 differs from FIGS. 11 and 12 above in that the side of the reflective layer RFL1 of the light-emitting element LE is stepped from the side of the first portion S1 of the semiconductor layer SEM2. Hereinafter, descriptions of the same components will be simplified or omitted, and differences will be described in detail.

Referring to FIG. 15, side surfaces of the first portion S1 of the second semiconductor layer SEM2 and the first insulating layer INS1 may be mutually aligned and matched.

The reflective layer RFL1 may be located on the first insulating layer INS1 to surround outer surfaces of the first semiconductor layer SEM1, the active layer MQW, and the second portion S2 of the second semiconductor layer SEM2. Accordingly, the lateral surface of the reflective layer RFL1 has a step with the first portion S1 of the second semiconductor layer SEM2.

The second insulating layer INS2 is located along the outer surfaces of the reflective layer RFL1 and the first portion S1 of the second semiconductor layer SEM2. Accordingly, the second insulating layer INS2 has a step at one end of the reflective layer RFL1. The second insulating layer INS2 has a step between the first portion S1 and the second portion S2 of the second semiconductor layer SEM2.

As may be seen from the above example, the reflective layer RFL1 covering at least the outer surface of the active layer MQW is connected to the connection electrode 150, and not connected to the common electrode CE. Therefore, when the connection electrode 150 of the light-emitting element LE and the common electrode CE conduct through the reflective layer RFL1, the likelihood of an electrical short circuit may be reduced or prevented.

Hereinafter, a manufacturing process of the display device 10 according to one or more embodiments will be described with reference to other drawings.

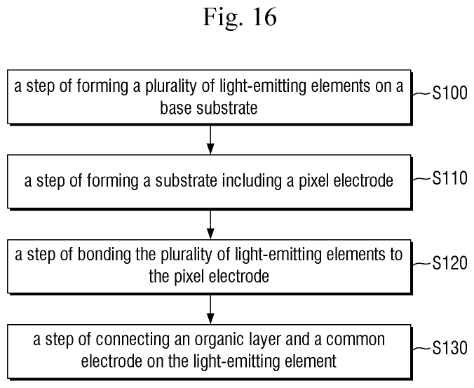

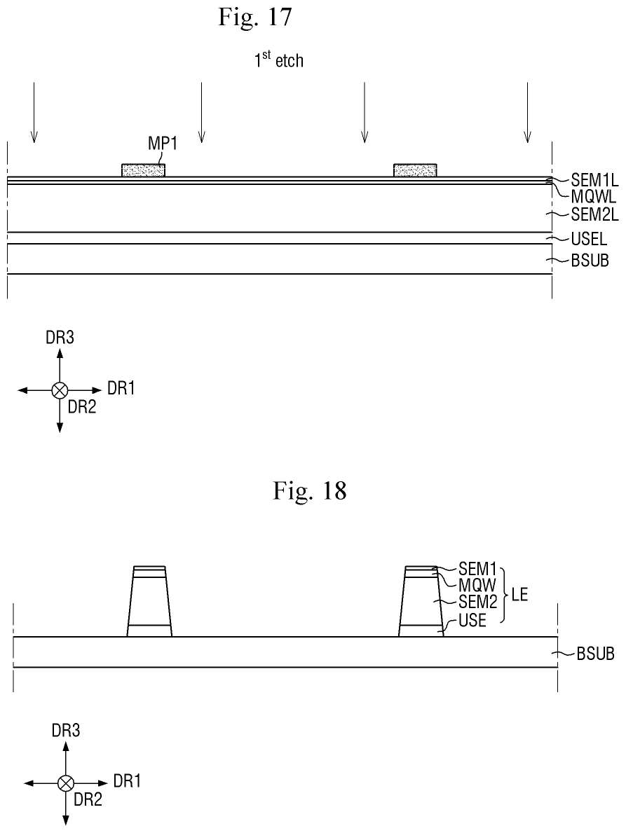

FIG. 16 is a flowchart illustrating a method of manufacturing a display device according to one or more embodiments. FIGS. 17 to 37 are diagrams to illustrate a method of manufacturing a display device according to one or more embodiments.

FIGS. 17 through 37 illustrate structures according to the formation order of each layer of the display device 10 as cross-sectional views. FIGS. 17 to 37 mainly show the manufacturing process of the light-emitting element part LEP of the display device 10, and these may generally correspond to the cross-sectional view of FIG. 6. In addition, in the following, the first light-emitting area EA1 and the second light-emitting area EA2 of the display device 10 are mainly shown. Hereinafter, a manufacturing method of the display device shown in FIGS. 17 to 37 will be described in conjunction with FIG. 16.

Referring to FIG. 16, a method of manufacturing a display device 10 according to one or more embodiments may include an operation S100 of forming a plurality of light-emitting elements on a base substrate, an operation S110 of forming a substrate including a pixel electrode, an operation S120 of bonding the plurality of light-emitting elements to the pixel electrodes, and an operation S130 of connecting an organic layer and a common electrode on the light-emitting elements.

First, referring to FIGS. 17 and 18, a plurality of light-emitting elements LE are formed on a base substrate BSUB.

For example, the base substrate BSUB is prepared. The base substrate BSUB may be a sapphire substrate Al₂O₃ or a silicon wafer including silicon. However, it is not limited thereto, and in one or more embodiments, a case where the base substrate BSUB is a sapphire substrate will be described as an example.

A plurality of semiconductor material layers USEL, SEM2L, MQWL, and SEM1L are formed on the base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and/or the like, and suitably formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group, such as a methyl or ethyl group. For example, the precursor material may be a compound, such as trimethyl gallium (Ga(CH₃)₃), trimethyl aluminum (Al(CH₃)₃), triethyl phosphate ((C₂H₅)₃PO₄), but are not limited thereto.

For example, a third semiconductor material layer USEL is formed on the base substrate BSUB. While the drawings illustrate the third semiconductor material layer USEL being further stacked, it is not limited to this, and a plurality of layers may be formed. The third semiconductor material layer USEL may reduce a lattice constant difference between a second semiconductor material layer SEM2L and the base substrate BSUB. For example, the third semiconductor material layer USEL may include an undoped semiconductor, which may be an n-type or p-type undoped material. In one or more embodiments, the third semiconductor material layer USEL may be at least one of undoped InAlGaN, GaN, AlGaN, InGaN, AlN, or InN but is not limited thereto.

The second semiconductor material layer SEM2L, the active material layer MQWL, and the first semiconductor material layer SEM1L are sequentially formed on the third semiconductor material layer USEL by using the above-described method.

Then, the plurality of semiconductor material layers USEL, SEM2L, MQWL, and SEM1L are etched to form the plurality of light-emitting elements LE1 and LE3.

For example, a plurality of first mask patterns MP1 are formed on the first semiconductor material layer SEM1L. The first mask pattern MP1 may be a hard mask including an inorganic material, or a photoresist mask including an organic material. The first mask pattern MP1 reduces or prevents the likelihood of the lower plurality of semiconductor material layers USEL, SEM2L, MQWL, and SEM1L being etched. Then, a portion of the plurality of semiconductor material layers is etched (1^{st} etch) using the plurality of first mask patterns MP1 as a mask to form the plurality of light-emitting elements LE.

As shown in FIG. 18, on the base substrate BSUB, the plurality of semiconductor material layers USEL, SEM2L, MQWL, and SEM1L that are non-overlapping with the first mask pattern MP1 are etched and removed, and the portions that are not etched overlapping with the first mask pattern MP1 may be formed into the plurality of light-emitting elements LE.

The semiconductor material layers may be etched by conventional methods. For example, the process of etching the semiconductor material layers may be dry etching, wet etching, reactive ion etching (RIE), deep reactive ion etching (DRIE), inductively coupled plasma reactive ion etching (ICP-RIE), and/or the like. In the case of dry etching methods, anisotropic etching is possible, which may be suitable for vertical etching. When utilizing the etching method described above, the etchant may be Cl₂ or O₂. However, it is not limited thereto.

The plurality of semiconductor material layers USEL, SEM2L, MQWL, and SEM1L overlapping the first mask pattern MP1 are not etched but are formed into the plurality of light-emitting elements LE. Thus, the plurality of light-emitting elements LE are formed including a third semiconductor layer USE, the second semiconductor layer SEM2, the active layer MQW, and the first semiconductor layer SEM1.

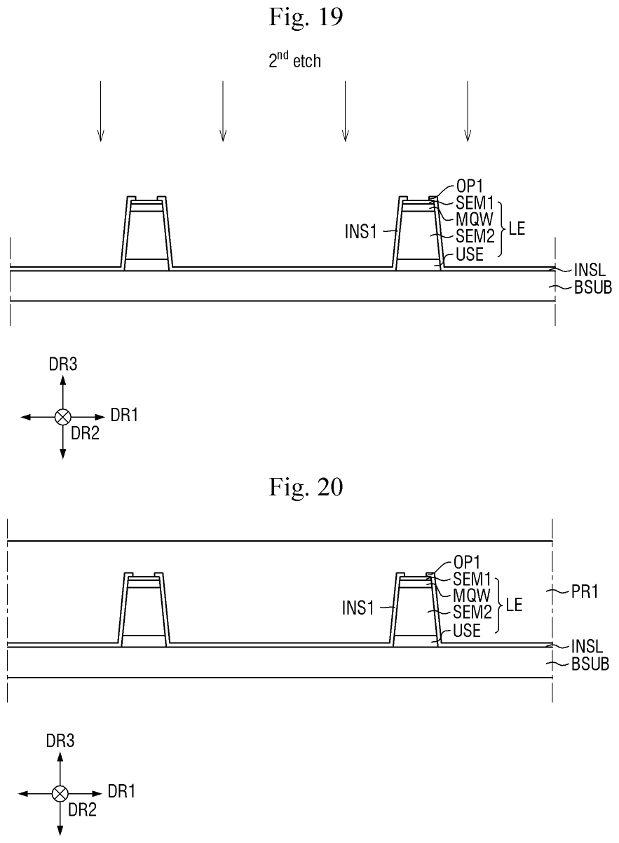

Referring to FIG. 19, a first insulating layer INS1 having the first opening OP1 is formed on the base substrate BSUB on which the light-emitting element LE is formed. The first opening OP1 is formed on the upper surface of the light-emitting element LE.

For example, the insulating material layer INSL is formed on the outer surfaces of the plurality of light-emitting elements LE. The insulating material layer INSL may be formed on the entire surface of the base substrate BSUB and may be formed not only on the light-emitting element LE, but also on the upper surface of the base substrate BSUB exposed by the light-emitting element LE.

Then, a second etch is performed to partially remove the insulating material layer INSL to form the first insulating layer INS1 having the first opening OP1 on the upper surface of the light-emitting element LE.

For example, the second etching process may be performed in which the insulating material layer INSL is partially removed such that the insulating material layer INSL exposes at least a portion of the upper surface of the light-emitting element LE, while enclosing the sides of the light-emitting element LE. For example, in this process, a portion of the insulating material layer INSL may be removed to expose the upper surface of the first semiconductor layer SEM1 of the light-emitting element LE. The process of partially removing the insulating material layer INSL may be performed by a process, such as an etch-back after dry etching, which is anisotropic etching, but is not limited thereto.

Next, referring to FIGS. 20 to 24, the reflective layer RFL having a desired height is formed on the first insulating layer INS by using a photoresist PR1.

For example, referring to FIG. 20, the first photoresist PR1 is applied to cover the entire upper surface of the light-emitting element LE to be planarized.

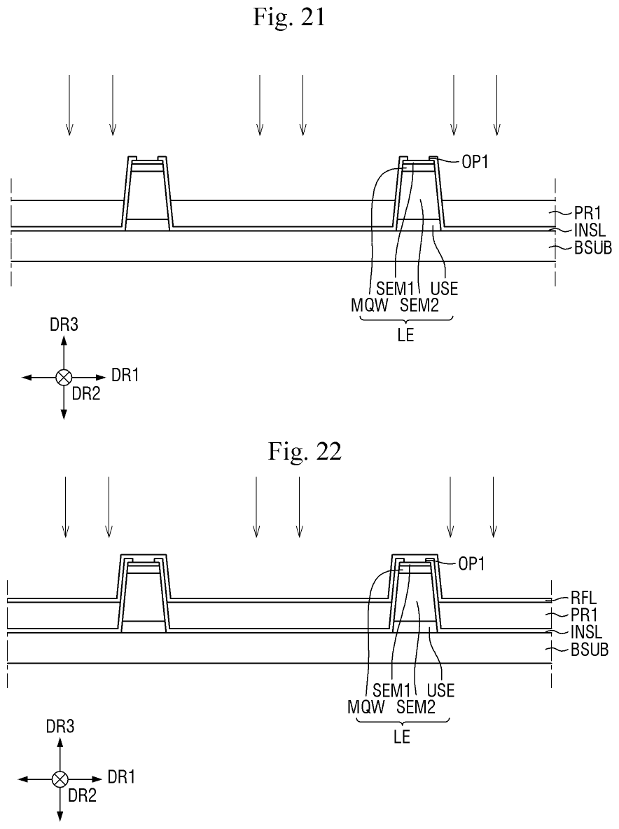

Then, referring to FIG. 21, the first photoresist PR1 is partially exposed to expose portions of the upper and side surfaces of the light-emitting element. For example, a portion of the first photoresist PR1 may be removed to expose at least the first semiconductor layer SEM1 or the active layer MQW of the light-emitting element LE.

Next, referring to FIGS. 22 to 24, the reflective layer RFL is formed on the first photoresist PR1 where a portion of the light-emitting element LE is exposed. The reflective layer RFL may be formed in the same manner as the manufacturing process of the first insulating layer INS1 described above. For example, at least one reflective material layer is stacked on the base substrate BSUB. Thereafter, a second photoresist PR2 may be coated on the light-emitting element LE and etched through an etching process to form the reflective layer RFL surrounding the light-emitting element LE. Accordingly, the reflective layer RFL surrounding at least the first semiconductor layer SEM1 of the light-emitting element LE or the active layer MQW may be formed on the first insulating layer INS1. Also, the reflective layer RFL contacts the first semiconductor layer SEM1 through the first opening OP1.

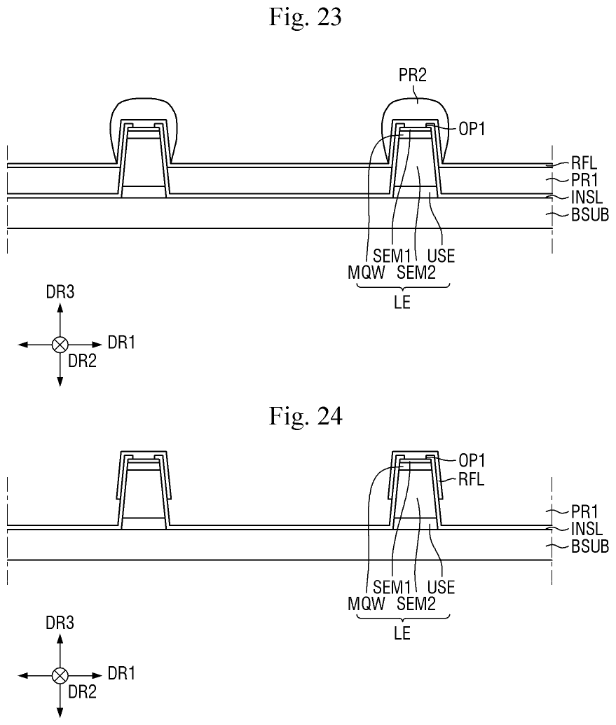

As another example, the reflective layer RFL formed on the first photoresist PR1 may be removed by a lift-off process instead of etching using the second photoresist PR2 described with reference to FIG. 23. Subsequently, the first photoresist PR1 remaining on the base substrate BSUB is removed by stripping or ashing.

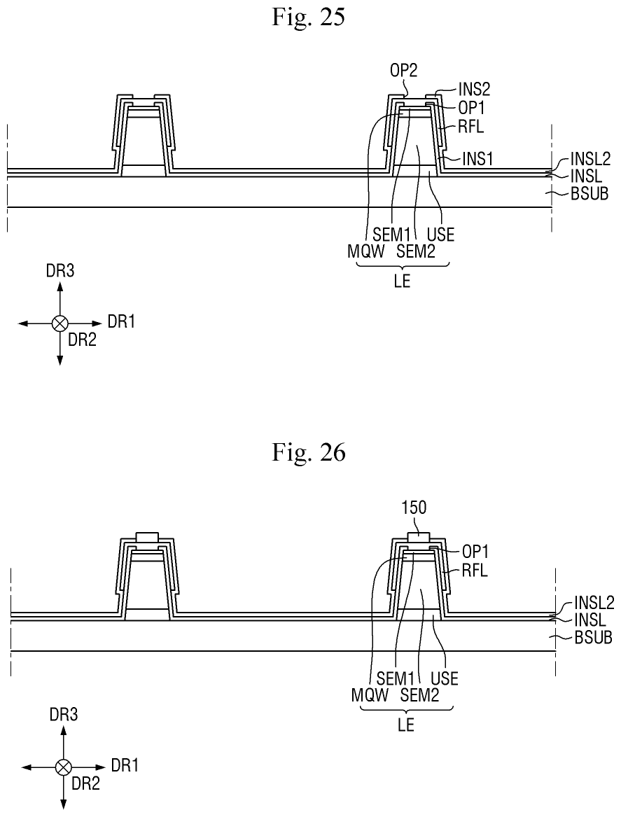

Next, referring to FIG. 25, the second insulating layer INS2 having the second opening OP2 is formed on the base substrate BSUB on which the light-emitting element LE is formed. The second opening OP2 is formed on the upper surface of the light-emitting element LE. The second insulating layer INS2 may be formed in the same manner as the manufacturing process of the first insulating layer INS1 described above. For example, the insulating material layer INSL is formed on the base substrate BSUB on which the light-emitting element LE is formed, and the second etch is performed to partially remove the insulating material layer INSL to form the second insulating layer INS2 having the second opening OP2 on the upper surface of the light-emitting element LE.

Next, referring to FIG. 26, the connection electrode 150 is formed in the second opening OP2. The connection electrode 150 may be formed by laminating a layer of electrode material on the base substrate BSUB, and by then etching the electrode material through an etching process to form the connection electrode 150 within the second opening OP2. The connection electrode 150 may contact the reflective layer RFL through the second opening OP2.

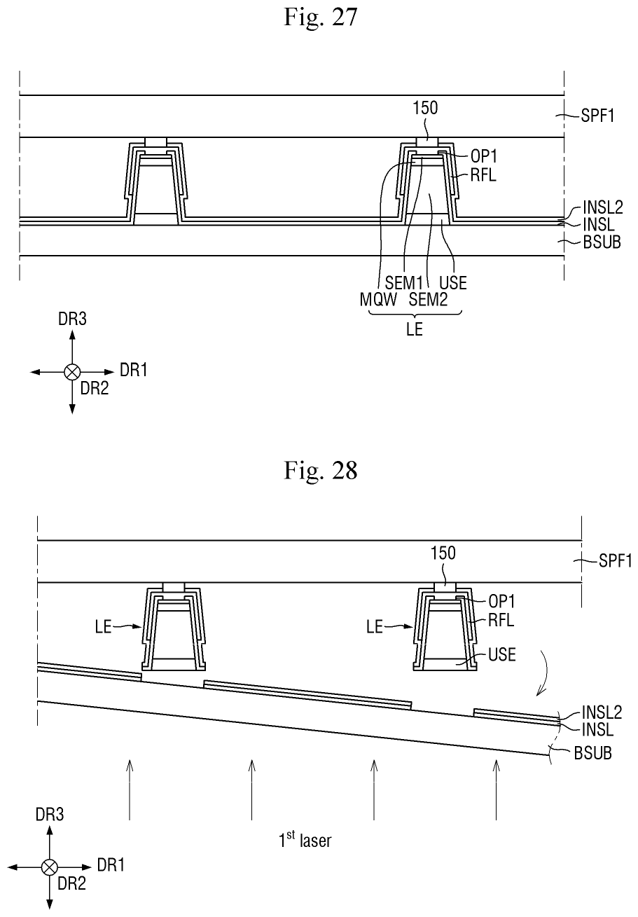

Next, referring to FIG. 27, a first support film SPF1 is attached to the plurality of light-emitting elements LE of the base substrate BSUB manufactured in FIG. 26.

For example, the first support film SPF1 is attached to the plurality of light-emitting elements LE. The first support film SPF1 may be aligned on the plurality of light-emitting elements LE, and may be attached to each of the connection electrodes 150 of the plurality of light-emitting elements LE. The plurality of light-emitting elements LE may be arranged in a large number, so that they may be attached to the first support film SPF1 without being detached.

The first support film SPF1 may comprise a support layer and an adhesive layer located on the support layer. The support layer may be made of a transparent, mechanically stable material that allows light to penetrate. For example, the support layer may include a transparent polymer, such as polyester, polyacrylic, polyepoxy, polyethylene, polystyrene, polyethylene terephthalate, or the like. The adhesive layer may include an adhesive material for bonding the light-emitting element LE. For example, the adhesive material may include urethane acrylate, epoxy acrylate, polyester acrylate, and/or the like. The adhesive material may be a material whose adhesion changes as ultraviolet (UV) light or heat is applied, such that the adhesive layer may be suitably separated from the plurality of light-emitting elements LE.

Then, referring to FIG. 28, the base substrate BSUB is irradiated with a first laser to separate the plurality of light-emitting elements LE1 and LE3 from the base substrate BSUB. The base substrate BSUB is separated from each third semiconductor layer USE of the plurality of light-emitting elements LE.

The process for separating the base substrate BSUB may be separated by a laser lift off (LLO) process. The laser lift off process utilizes a laser, and a KrF excimer laser (e.g., about 248 nm wavelength) may be used as the source. The energy density of the excimer laser is irradiated in the range of about 550 mJ/cm² to about 950 mJ/cm², and the incident area may be in the range of 50×50 μm² to 1×1 cm², but is not limited thereto. The base substrate BSUB may be separated from the plurality of light-emitting elements LE by irradiating the base substrate BSUB with the laser.

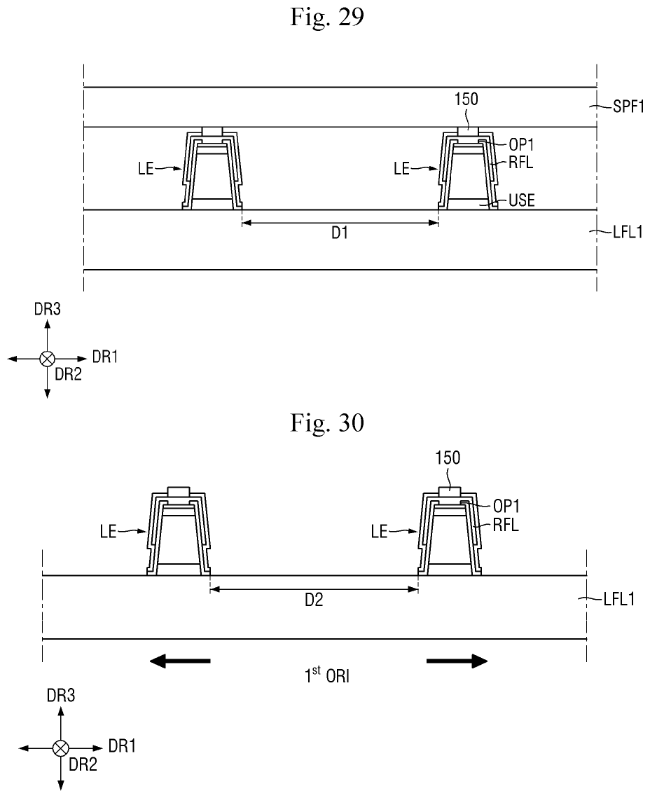

Next, referring to FIG. 29, a first transfer film LFL1 is attached to the plurality of light-emitting elements LE separated from the base substrate BSUB.

For example, the first transfer film LFL1 is attached to each of the third semiconductor layers USE of the plurality of light-emitting elements LE. The first transfer film LFL1 may be aligned on the plurality of light-emitting elements LE, and may be attached to each third semiconductor layer USE of the plurality of light-emitting elements LE.

The first transfer film LFL1 may include a stretchable material. The stretchable material may include, for example, polyolefine, polyvinyl chloride (PVC), elastomeric silicone, elastomeric polyurethane, elastomeric polyisoprene, and/or the like. The first transfer film LFL1 may also include the support layer and the adhesive layer, such as the first support film SPF1 described above, to bond and support the plurality of light-emitting elements LE. The plurality of light-emitting elements LE are spaced apart from each other by a first spacing D1 (e.g., predetermined first spacing) and arranged.

Next, referring to FIG. 30, the first support film SPF1 is separated from the plurality of light-emitting elements LE. The first support film SPF1 may be physically or naturally separated after applying ultraviolet light or heat to the first support film SPF1 to reduce the adhesion of the adhesive layer of the first support film SPF1. The plurality of light-emitting elements LE may be located on the first transfer film LFL1 spaced apart by the first spacing D1. Thereafter, the first transfer film LFL1 is stretched (1^{st} ORI). The first transfer film LFL1 may be stretched two-dimensionally in the first and/or second directions DR1 and DR2.

As the first transfer film LFL1 is stretched, a separation distance of the plurality of light-emitting elements LE bonded on the first transfer film LFL1 may become a second spacing D2, which is greater than the first spacing D1 in FIG. 29. Accordingly, the plurality of light-emitting elements LE may be located in a dot shape at the second spacing D2 on the first transfer film LFL1.

The stretching strength (or tensile strength) of the first transfer film LFL1 may be adjusted according to a desired spacing between the light-emitting elements LE, and may be, for example, about 120 gf/inch. However, it is not limited thereto.

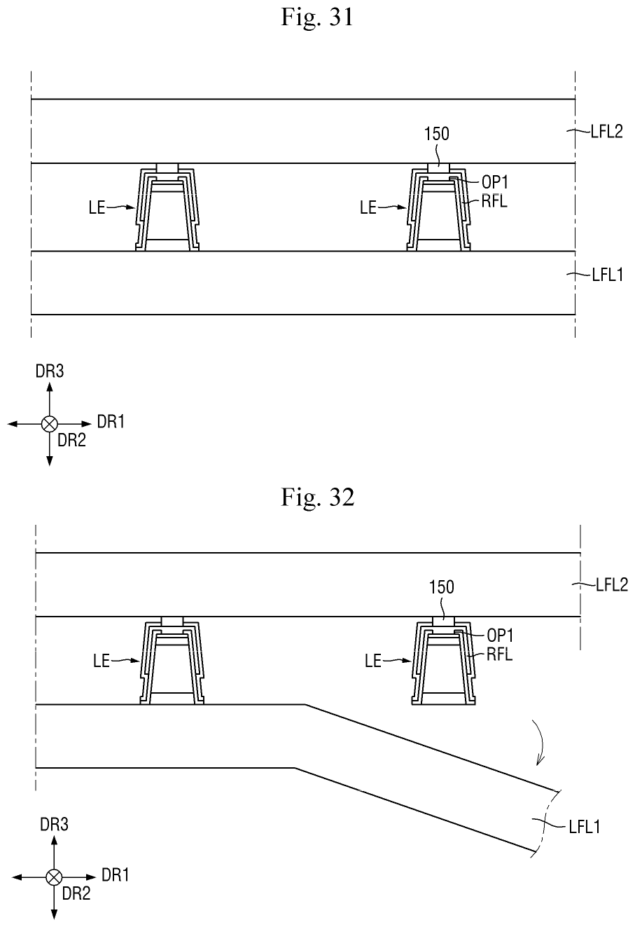

Next, referring to FIG. 31, the second transfer film LFL2 is attached on the plurality of light-emitting elements LE from which the first support film SPF1 is separated. The second transfer film LFL2 may be aligned on the plurality of light-emitting elements LE, and may be attached to each connection electrode 150 of the plurality of light-emitting elements LE. The second transfer film LFL2 includes the support layer and the adhesive layer in the same manner as the above-described the first transfer film LFL1, and a detailed description will not be repeated.

Subsequently, referring to FIG. 32, the first transfer film LFL1 is separated from the plurality of light-emitting elements LE. After reducing the adhesive strength of the adhesive layer of the first transfer film LFL1 by applying ultraviolet light or heat to the first transfer film LFL1, the first transfer film LFL1 may be physically or naturally separated.

Next, the second transfer film LFL2 is stretched (2^{nd} ORI) and the first transfer film LFL1 is separated.

The second transfer film LFL2 may be stretched two-dimensionally in the first and/or second directions DR1 and DR2. As the second transfer film LFL2 is stretched, the separation distance between the plurality of light-emitting elements LE bonded on the second transfer film LFL2 may further increase. The stretching strength (or tensile strength) of the second transfer film LFL2 may be adjusted according to a desired spacing between the light-emitting elements LE, and may be, for example, about 270 gf/inch. However, it is not limited thereto.

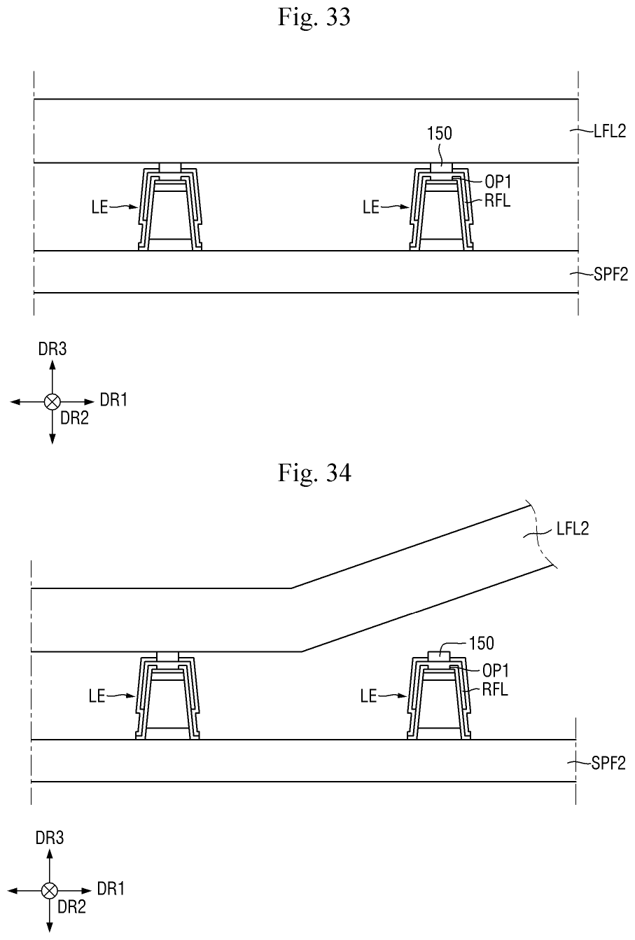

Next, referring to FIG. 33, a second support film SPF2 is attached on the plurality of light-emitting elements LE from which the first transfer film LFL1 is separated. The second support film SPF2 may be aligned on the plurality of light-emitting elements LE, and may be attached to each third semiconductor layer USE of the plurality of light-emitting elements LE. The second support film SPF2 includes the support layer and the adhesive layer in the same manner as the above-described the first support film SPF1, and a detailed description will not be repeated.

Next, referring to FIG. 34, the second transfer film LFL2 is separated. For example, the second transfer film LFL2 attached to the connection electrode 150 of the plurality of light-emitting elements LE is separated. Because the separation process of the second transfer film LFL2 is the same as the above-described separation of the first transfer film LFL1, the description thereof is not repeated. The second transfer film LFL2 may be separated from the connection electrodes 150 of the plurality of light-emitting elements LE and removed.

It has been described as an example that two stretching processes are performed but is not limited thereto. The stretching process may be performed multiple times.

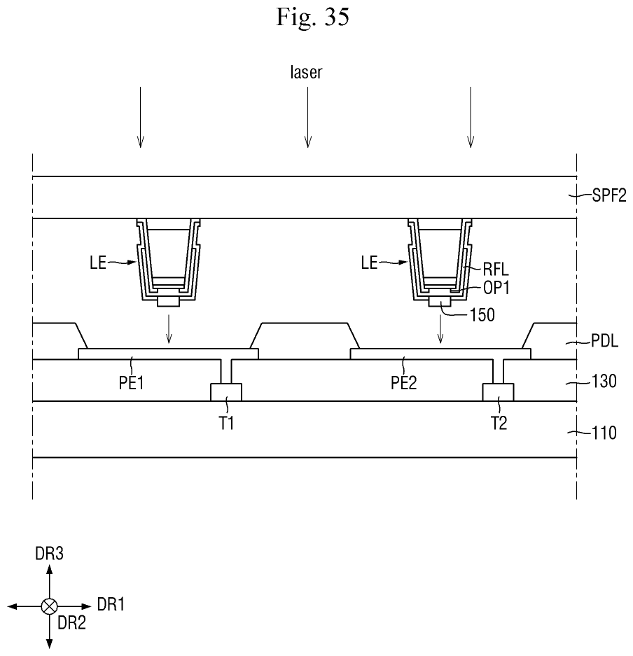

Next, referring to FIG. 35, the second support film SPF2 is bonded to the substrate 110 and the plurality of light-emitting elements LE are adhered to the first and second pixel electrodes PE1 and PE2.

For example, the second support film SPF2 is aligned on the substrate 110. At this time, the connection electrode 150 of the light-emitting element LE formed on the second support film SPF2 is aligned so as to face the substrate 110. As shown in FIG. 6, the substrate 110 may have the plurality of pixel electrodes PE1 and PE2 and the bank layer BNL formed thereon.

Next, the substrate 110 and the second support film SPF2 are bonded. For example, the connection electrode 150 of the light-emitting element LE formed on the second support film SPF2 are contacted to the pixel electrodes PE1 and PE2 of the substrate 110. At this time, the connection electrode 150 of the light-emitting element LE is in contact with the pixel electrodes PE1 and PE2. Next, the substrate 110 and the second support film SPF2 are bonded by melting and bonding the connection electrode 150 of the light-emitting element LE and the pixel electrodes PE1 and PE2. At this time, the plurality of light-emitting elements LE are bonded to the upper surfaces of the pixel electrodes PE1 and PE2.

As for the melt bonding, a laser may be irradiated onto the pixel electrodes PE1 and PE2 on the second support film SPF2. The laser-irradiated pixel electrodes PE1 and PE2 may conduct high heat from the laser to bond the interface of the connection electrode 150 of the light-emitting element LE and the pixel electrodes PE1 and PE2. For example, the pixel electrodes PE1 and PE2 may include copper (Cu) having suitable heat conduction, and may have suitable adhesive properties with the connection electrode 150 of the light-emitting element LE. The source of the laser used for the melt bonding may be a YAG.

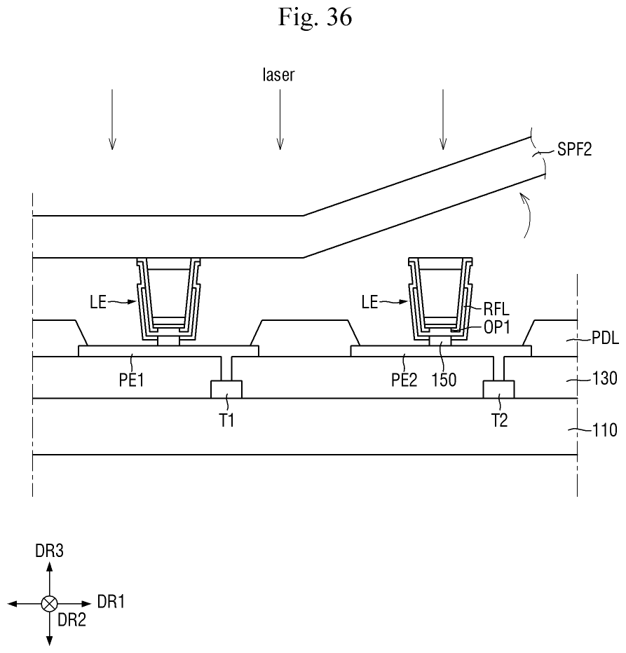

Next, referring to FIG. 36, the second support film SPF2 is separated from the plurality of light-emitting elements LE.

For example, the second support film SPF2 is separated from the third semiconductor layer USE of the light-emitting element LE. The process of separating the second support film SPF2 may use a laser lift off (LLO) process. The laser lift-off process uses a laser, and a KrF excimer laser (e.g., about 248 nm wavelength) may be used as a source. The energy density of the excimer laser is irradiated in the range of about 550 mJ/cm² to about 950 mJ/cm², and the incident area may be in the range of about 50×50 μm² to about 1×1 cm², but is not limited thereto. By irradiating the second support film SPF2 with the laser, the second support film SPF2 may be separated from the light-emitting element LE.

In another example, the second support film SPF2 may be physically separated in addition to the laser lift-off process. Because the bonding strength between the second support film SPF2 and the light-emitting element LE is less than the bonding strength between the connection electrode 150 of the light-emitting element LE and the pixel electrodes PE1 and PE2 that are melt-bonded, the second support film SPF2 may be physically separated based on the difference in bonding strength.

Thereafter, the third semiconductor layer USE may be removed by ashing. The third semiconductor layer USE may be partially left behind.

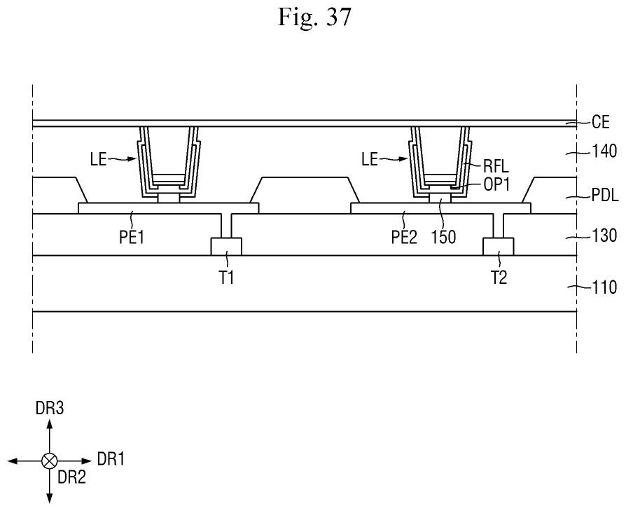

Next, referring to FIG. 37, an organic layer 140 is formed on the substrate 110 on which the light-emitting elements LE are formed. The organic layer 140 may be formed on the plurality of pixel electrodes PE1 and PE2 and the pixel-defining layer PDL. The organic layer 140 may be located on each light-emitting area, and may be spaced apart from each other between adjacent light-emitting areas. The organic layer 140 may be formed by being coated using a solution process, such as spin coating or inkjet printing and then patterned through an exposure process. The organic layer 140 may be formed to have a height equal to or less than that of the second semiconductor layer SEM2 of the light-emitting element LE, but is not limited thereto. As a result, one end surface of the light-emitting element LE is exposed.

Next, the common electrode CE is formed on the light-emitting element LE and the organic layer 140. The common electrode CE is continuously formed over the entire display area. The common electrode CE covers the organic layer 140 and the light-emitting element LE, and directly contacts them. The common electrode CE is formed in direct contact with the upper surface of the second semiconductor layer SEM2 of the light-emitting element LE. In another modified example, when at least a portion of the third semiconductor layer SEM3 is left, the common electrode CE is formed in direct contact with the upper surface of the third semiconductor layer SEM3 of the light-emitting element LE.

Then, as shown in FIG. 6a, the display device 10 according to one or more embodiments is manufactured by forming a wavelength control layer and the color filter layer.

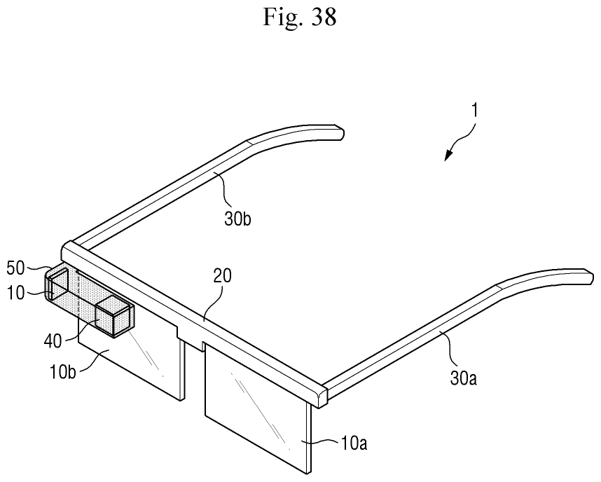

FIG. 38 is a diagram illustrating a virtual reality device including a display device according to one or more embodiments. FIG. 38 illustrates a virtual reality device 1 in which the display device 10 according to one or more embodiments is used.

Referring to FIG. 38, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 38 illustrates the virtual reality device 1 including the two legs 30a and 30b. However, the disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 38, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 38 illustrates that the display device housing 50 is located at a right end of the support frame 20. However, one or more embodiments of the disclosure is not limited thereto. For example, the display device housing 50 may be located at a left end of the support frame 20. In this case, the image displayed on the display device 10 may be reflected from the reflective member 40 and provided to the user's left eye via the left-eye lens 10a. Thus, the user may view the virtual reality image displayed via the left eye. As another example, the display device housing 50 may be located at each of the left end and the right end of the support frame 20. In this case, the user may view the virtual reality image via both the left eye and the right eye.

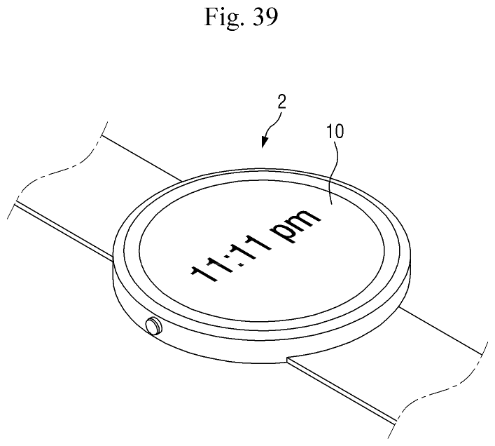

FIG. 39 is a diagram illustrating a smart device including a display device according to one or more embodiments.

Referring to FIG. 39, a display device 10 according to one or more embodiments may be applied to a smart watch 2 as one of smart devices.

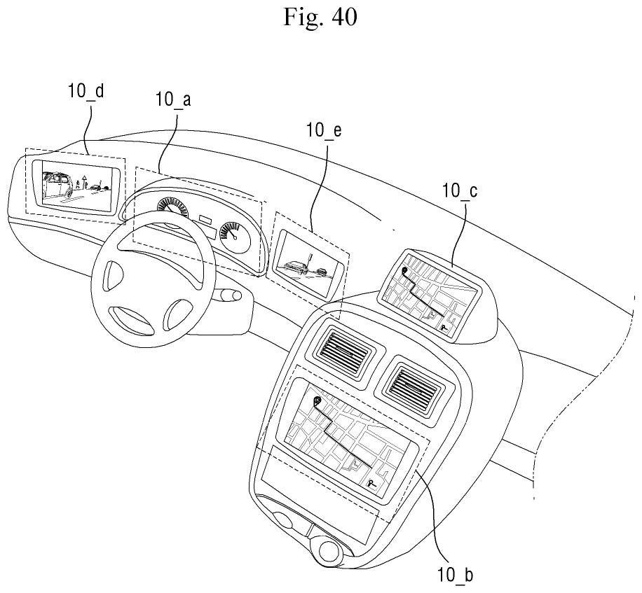

FIG. 40 illustrates a vehicle in which display devices according to one or more embodiments are used.

Referring to FIG. 40, the display devices 10_a, 10_b, and 10_c according to one or more embodiments may be applied to the dashboard of the vehicle, applied to the center fascia of the vehicle, or applied to a CID (Center Information Display) located on the dashboard of the vehicle. Further, each of the display devices 10_d and 10_e according to one or more embodiments may be applied to each room mirror display that replaces each of side-view mirrors of the vehicle.

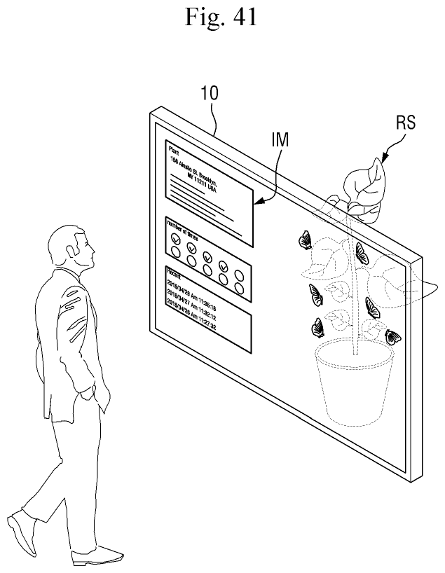

FIG. 41 is a diagram illustrating a transparent display device including a display device according to one or more embodiments.

Referring to FIG. 41, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate 110 of the display device 10 shown in FIG. 7 may include a light-transmitting portion that may transmit light therethrough or may be made of a material that may transmit light therethrough.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A light-emitting element comprising:
a second semiconductor layer;
an active layer above the second semiconductor layer;
a first semiconductor layer above the active layer;
a first insulating layer surrounding side surfaces of the first semiconductor layer, the active layer, and the second semiconductor layer and an upper surface of the first semiconductor layer, and defining a first opening at the upper surface of the first semiconductor layer;
a reflective layer surrounding side surfaces of the first semiconductor layer and the active layer and an upper surface of the first semiconductor layer on the first insulating layer; and
a second insulating layer on the reflective layer and on a portion of the first insulating layer on which the reflective layer is not located, defining a second opening on an upper surface of the first semiconductor layer, and having one end having a step with one end of the reflective layer.

2. The light-emitting element of claim 1, wherein the reflective layer directly contacts the first semiconductor layer through the first opening.

3. The light-emitting element of claim 1, wherein one end of the reflective layer surrounds a portion of an outer surface of the second semiconductor layer on the first insulating layer, and
wherein the reflective layer exposes the first insulating layer corresponding to at least a portion of the second semiconductor layer.

4. The light-emitting element of claim 3, wherein the second insulating layer surrounds side surfaces of the first semiconductor layer, the active layer, and the second semiconductor layer, and covers one end of the reflective layer.

5. The light-emitting element of claim 1, wherein the first semiconductor layer, the active layer, and the second semiconductor layer are shaped like a column or like a shape that narrows in width toward the first semiconductor layer.

6. The light-emitting element of claim 1, further comprising a connection electrode on the reflective layer exposed by the second opening.

7. The light-emitting element of claim 1, further comprising a third semiconductor layer on one surface of the second semiconductor layer,
wherein one end of the reflective layer is aligned with one end of the second semiconductor layer.

8. The light-emitting element of claim 6, wherein the second semiconductor layer comprises a first portion having a first width, and a second portion having a second width,
wherein the second width is less than the first width,
wherein the second portion is closer to the connection electrode than the first portion, and
wherein the first insulating layer and the reflective layer surround side surfaces of the second portion.

9. The light-emitting element of claim 8, wherein a width of the active layer and a width of the first semiconductor layer are less than a width of the second portion of the second semiconductor layer.

10. The light-emitting element of claim 8, wherein a side surface of the reflective layer is aligned with a side surface of the first portion of the second semiconductor layer.

11. The light-emitting element of claim 10, further comprising a metal layer surrounding the second semiconductor layer on the second insulating layer,
wherein the metal layer and the reflective layer do not contact each other.

12. The light-emitting element of claim 10, further comprising a metal layer surrounding the first portion of the second semiconductor layer on the second insulating layer,
wherein the metal layer and the reflective layer do not contact each other.

13. The light-emitting element of claim 8, wherein a side surface of the first insulating layer is aligned with a side surface of a first portion of the second semiconductor layer.

14. The light-emitting element of claim 13, wherein the second insulating layer covers one end of the reflective layer.

15. The light-emitting element of claim 8, further comprising a connection electrode on the reflective layer exposed by the second opening.

16. A display device comprising:
a substrate;
a pixel electrode above the substrate;
light-emitting elements above the pixel electrode;
an organic layer above the pixel electrode, and between the light-emitting elements; and
a common electrode above the organic layer and the light-emitting elements,
wherein the light-emitting elements comprise,
a second semiconductor layer;
an active layer above the second semiconductor layer;
a first semiconductor layer above the active layer;
a first insulating layer surrounding side surfaces of the first semiconductor layer, the active layer, and the second semiconductor layer and an upper surface of the first semiconductor layer, and defining a first opening at the upper surface of the first semiconductor layer;
a reflective layer surrounding side surfaces of the first semiconductor layer and the active layer and an upper surface of the first semiconductor layer on the first insulating layer; and
a second insulating layer on the reflective layer and a portion of the first insulating layer on which the reflective layer is not located, defining a second opening on an upper surface of the first semiconductor layer, and having one end having a step with one end of the reflective layer.

17. The display device of claim 16, wherein the light-emitting elements further comprise a connection electrode on the reflective layer exposed by the second opening,
wherein the connection electrode is connected to the pixel electrode, and
wherein the second semiconductor layer is connected to the common electrode.

18. The display device of claim 17, wherein one end of the reflective layer surrounds a portion of an outer surface of the second semiconductor layer on the first insulating layer, and
wherein the reflective layer exposes a first insulating layer corresponding to at least a portion of the second semiconductor layer.

19. The display device of claim 18, wherein the second insulating layer surrounds side surfaces of the first semiconductor layer, the active layer, and the second semiconductor layer, and covers one end of the reflective layer.

20. The display device of claim 19, wherein the reflective layer does not contact the common electrode.
